(19) United States
(12) Patent Application Publication
(10) Pub. No.: US 2023/0329047 A1
(43) Pub. Date: Oct. 12, 2023

(54) THIN FILM TRANSISTOR SUBSTRATE AND DISPLAY APPARATUS COMPRISING THE SAME

(71) Applicant: LG Display Co., Ltd., Seoul (KR)

(72) Inventors: YounGyoung CHANG, Paju-si (KR); WonSang RYU, Paju-si (KR); Youngjin YI, Paju-si (KR); Hanseok LEE, Paju-si (KR); SungSoo SHIN, Paju-si (KR); Jungyul YANG, Paju-si (KR); JungJune KIM, Paju-si (KR); Jihwan JUNG, Paju-si (KR); Soyang CHOI, Paju-si (KR); Yubeen LIM, Paju-si (KR)

(73) Assignee: LG Display Co., Ltd., Seoul (KR)

(21) Appl. No.: 18/132,847

(22) Filed: Apr. 10, 2023

(30) Foreign Application Priority Data
Apr. 11, 2022 (KR) 10-2022-0044664
Aug. 26, 2022 (KR) 10-2022-0107515

(51) Int. Cl. H01L 29/12; G09G 3/3233

(52) U.S. Cl. CPC H10K 59/126; G09G 3/3233; G09G 2300/0819; G09G 2300/0861; G09G 2300/0842

(57) ABSTRACT

A thin film transistor substrate can include a first thin film transistor on a substrate, the first thin film transistor including a first active layer and a first gate electrode; and a second thin film transistor on the substrate, the second thin film transistor including a second active layer and a second gate electrode, each of the second active layer and the second gate electrode being located farther away from the substrate than the first active layer and the first gate electrode. Also, the thin film transistor substrate can include a first insulating layer disposed between the first gate electrode and the second active layer; and a first connection electrode connecting the first gate electrode with the second active layer, in which the first connection electrode extends through a first contact hole in the first insulating layer and contacts both of the first gate electrode and the second active layer.

### CROSS-REFERENCE TO RELATED APPLICATIONS

This application claims priority to the Korean Patent Applications No. 10-2022-0044664 filed in the Republic of Korea on Apr. 11, 2022, and Korean Patent Application No. 10-2022-0107515 filed in the Republic of Korea on Aug. 26, 2022, the entireties of all of these applications are hereby incorporated by reference as if fully set forth herein.

### BACKGROUND

### Technical Field

The present disclosure relates to a thin film transistor substrate and a display apparatus comprising the same.

### Description of the Related Art

Since a thin film transistor can be manufactured on a glass substrate or a plastic substrate, it is widely used as a switching element or a driving element of a display apparatus, such as a liquid crystal display apparatus or an organic light emitting apparatus.

The display apparatus includes a plurality of pixels, and a circuit element including a plurality of thin film transistors is formed in each of the plurality of pixels. In particular, the number of thin film transistors required for each of the plurality of pixels is increasing for applying additional sensing circuit elements, and accordingly, the size of the circuitry for the pixels must be increased in consideration of the space of the thin film transistors. However, as more transistors are used for each pixel, this can increase the amount of space used which can lead to large pixels that are spaced farther apart and/or the resolution of the display may be reduced.

Therefore, in order to implement a display apparatus having a high resolution, a method capable of forming a large number of thin film transistors in a small pixel area is desired.

### SUMMARY OF THE DISCLOSURE

The present disclosure has been made in view of the above problems, and it is an object of the present disclosure to provide a thin film transistor substrate with a large number of thin film transistors in a small pixel area by placing multiple thin film transistors up and down on different layers, and a display device including the same.

In accordance with an aspect of the present disclosure, the above and other objects can be accomplished by the provision of a thin film transistor substrate comprising a substrate; a first thin film transistor provided on the substrate, the first thin film transistor including a first active layer and a first gate electrode; a second thin film transistor provided on the substrate, the second thin film transistor including a second active layer and a second gate electrode, each of the second active layer and the second gate electrode provided on the first active layer and the first gate electrode; a first insulating layer provided between the first gate electrode and the second active layer; and a first connection electrode connecting the first gate electrode with the second active layer, in which the first connection electrode is extended through a first contact hole in the first insulating layer, and in contact with each of the first gate electrode and the second active layer, and a display apparatus including the same.

In accordance with an aspect of the present disclosure, a display apparatus can include a light emitting element disposed on a substrate; a first thin film transistor disposed on the substrate and including a first active layer, the first thin film transistor being electrically connected to the light emitting element; a second thin film transistor disposed on the substrate and including a second active layer; and a first connection electrode directly connected between the first active layer and the second active layer, wherein the second active layer is located farther away from the substrate than the first active layer, and wherein a portion of the second active layer directly contacts both of an upper surface of the first connection electrode and a side surface of the first connection electrode.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a circuit diagram of one pixel provided in a display apparatus according to an embodiment of the present disclosure.

FIG. 2 is a plan view of one pixel provided in a display apparatus according to an embodiment of the present disclosure.

FIG. 3 is a schematic cross-sectional view of a display apparatus according to an embodiment of the present disclosure, and corresponds to cross-sections of a first thin film transistor, a second thin film transistor, and a third thin film transistor in FIG. 2.

FIG. 4 is a schematic cross-sectional view of a display apparatus according to another embodiment of the present disclosure, and corresponds to cross-sections of a first thin film transistor, a second thin film transistor, and a third thin film transistor in FIG. 2.

FIG. 5 is a schematic cross-sectional view of a display apparatus according to an embodiment of the present disclosure, and corresponds to cross-sections of a first thin film transistor, a fourth thin film transistor, and a fifth thin film transistor in FIG. 2.

FIG. 6 is a schematic plan view of a display apparatus according to an embodiment of the present disclosure, which is a plan view of a fourth thin film transistor region that is a rectangular dotted line region in FIG. 5.

FIG. 7 is a schematic cross-sectional view of a display apparatus according to another embodiment of the present disclosure, and corresponds to cross-sections of a first thin film transistor, a fourth thin film transistor, and a fifth thin film transistor in FIG. 2.

FIG. 8 is a schematic plan view of a display apparatus according to another embodiment of the present disclosure, which is a plan view of a fourth thin film transistor region that is a rectangular dotted line region in FIG. 7.

FIG. 9 is a schematic cross-sectional view of a display apparatus according to another embodiment of the present disclosure, and corresponds to cross-sections of a first thin film transistor, a fourth thin film transistor, and a fifth thin film transistor in FIG. 2.

FIG. 10 is a schematic plan view of a display apparatus according to another embodiment of the present disclosure, which is a plan view of a fourth thin film transistor region that is a rectangular dotted line region in FIG. 9.

FIG. 11 is a schematic cross-sectional view of a display apparatus according to another embodiment of the present disclosure, and corresponds to cross-sections of a first thin film transistor, a fourth thin film transistor, and a fifth thin film transistor in FIG. 2.

FIG. 12 is a schematic plan view of a display apparatus according to another embodiment of the present disclosure, which is a plan view of a fourth thin film transistor region that is a rectangular dotted line region in FIG. 11.

FIG. 13 is a schematic cross-sectional view of a display apparatus according to another embodiment of the present disclosure, and corresponds to cross-sections of a first thin film transistor, a fourth thin film transistor, and a fifth thin film transistor in FIG. 2.

FIG. 14 is a schematic cross-sectional view of a display apparatus according to another embodiment of the present disclosure, and corresponds to cross-sections of a first thin film transistor, a fourth thin film transistor, and a fifth thin film transistor in FIG. 2.

FIG. 15 is a schematic cross-sectional view of a display apparatus according to another embodiment of the present disclosure, and corresponds to cross-sections of a first thin film transistor, a fourth thin film transistor, and a fifth thin film transistor in FIG. 2.

FIG. 16 is a schematic cross-sectional view of a display apparatus according to another embodiment of the present disclosure, and corresponds to cross-sections of a first thin film transistor, a fourth thin film transistor, and a fifth thin film transistor in FIG. 2.

FIG. 17 is a schematic cross-sectional view of a display apparatus according to another embodiment of the present disclosure, and corresponds to cross-sections of a first thin film transistor, a fourth thin film transistor, and a fifth thin film transistor in FIG. 2.

FIG. 18 is a schematic cross-sectional view of a display apparatus according to another embodiment of the present disclosure, and corresponds to cross-sections of a first thin film transistor, a fourth thin film transistor, and a fifth thin film transistor in FIG. 2.

FIG. 19 is a schematic diagram of a display apparatus according to an embodiment of the present disclosure.

FIG. 20 is a circuit diagram of one pixel provided in a display apparatus according to another embodiment of the present disclosure.

FIG. 21 is a circuit diagram of one pixel provided in a display apparatus according to another embodiment of the present disclosure.

FIG. 22 is a circuit diagram of one pixel provided in a display apparatus according to another embodiment of the present disclosure.

### DETAILED DESCRIPTION OF THE EMBODIMENTS

Advantages and features of the present disclosure, and implementation methods thereof will be clarified through the following embodiments, described with reference to the accompanying drawings. The present disclosure can, however, be embodied in different forms and should not be construed as being limited to the embodiments set forth herein. Rather, these embodiments are provided so that this disclosure will be thorough and complete, and will fully convey the scope of the present disclosure to those skilled in the art. Further, the present disclosure is only defined by the scope of the claims.

The shapes, sizes, ratios, angles, and numbers disclosed in the drawings for describing embodiments of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In the situation in which “comprise,” “have,” and “include” described in the present specification are used, another part can also be present unless “only” is used. The terms in a singular form can include plural forms unless noted to the contrary.

In construing an element, the element is construed as including an error region although there is no explicit description thereof.

In describing a positional relationship, for example, when the positional order is described as “on,” “above,” “below,” “beneath,” and “next,” the situation of no contact therebetween can be included, unless “just” or “direct” is used.

If it is mentioned that a first element is positioned “on” a second element, it does not mean that the first element is essentially positioned above the second element in the figure. The upper part and the lower part of an object concerned can be changed depending on the orientation of the object. Consequently, the situation in which a first element is positioned “on” a second element includes the situation in which the first element is positioned “below” the second element as well as the situation in which the first element is positioned “above” the second element in the figure or in an actual configuration.

In describing a temporal relationship, for example, when the temporal order is described as “after,” “subsequent,” “next,” and “before,” a situation which is not continuous can be included, unless “just” or “direct” is used.

It will be understood that, although the terms “first,” “second,” etc. can be used herein to describe various elements, these elements should not be limited by these terms. These terms are only used to distinguish one element from another, and may not define order or sequence. For example, a first element could be termed a second element, and, similarly, a second element could be termed a first element.

It should be understood that the term “at least one” includes all combinations related with any one item. For example, “at least one among a first element, a second element and a third element” can include all combinations of two or more elements selected from the first, second and third elements as well as each element of the first, second and third elements.

Features of various embodiments of the present disclosure can be partially or overall coupled to or combined with each other, and can be variously inter-operated with each other and driven technically. The embodiments of the present disclosure can be carried out independently from each other, or can be carried out together in a co-dependent relationship.

In the drawings, the same or similar elements are denoted by the same reference numerals even though they are depicted in different drawings.

In the embodiments of the present disclosure, a source electrode and a drain electrode are distinguished from each other, for convenience of explanation. However, the source electrode and the drain electrode are used interchangeably. Thus, the source electrode can be the drain electrode, and the drain electrode can be the source electrode. Also, the source electrode in any one embodiment of the present disclosure can be the drain electrode in another embodiment of the present disclosure, and the drain electrode in any one embodiment of the present disclosure can be the source electrode in another embodiment of the present disclosure.

In one or more embodiments of the present disclosure, for convenience of explanation, a source region is distinguished from a source electrode, and a drain region is distinguished from a drain electrode. However, embodiments of the present disclosure are not limited to this structure. For example, a source region can be a source electrode, and a drain region can be a drain electrode. Also, a source region can be a drain electrode, and a drain region can be a source electrode.

Further, all the components of each display apparatus according to all embodiments of the present disclosure are operatively coupled and configured.

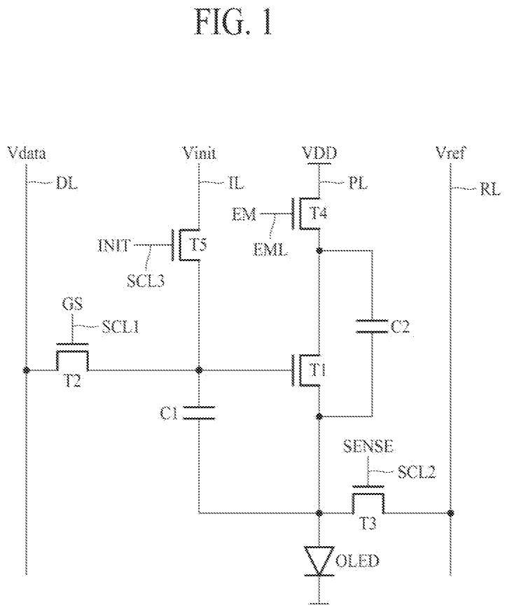

FIG. 1 is a circuit diagram of one pixel provided in a display apparatus according to an embodiment of the present disclosure.

As shown in FIG. 1, the display apparatus according to an embodiment of the present disclosure includes first to fifth thin film transistors T1, T2, T3, T4, and T5 and first to second capacitors C1 and C2.

The first thin film transistor T1 is a driving thin film transistor, and the second to fifth thin film transistors T2 to T5 are switching thin film transistors.

The first thin film transistor T1 is switched according to the data voltage Vdata supplied from the second thin film transistor T2, generates a data current from the driving voltage VDD supplied from the power line PL, and supplies it to the organic light emitting diode OLED.

The second thin film transistor T2 is switched according to the gate signal GS supplied to the first scan line SCL1 and supplies the data voltage Vdata supplied from the data line DL to the first thin film transistor T1.

The third thin film transistor T3 is for sensing a threshold voltage deviation of the first thin film transistor T1, which causes a decrease in image quality, in a sensing mode, and supplies a current of the first thin film transistor T1 to the reference line RL in response to a sensing control signal SENSE supplied from the second scan line SCL2. A reference voltage Vref is supplied to the reference line RL.

The fourth thin film transistor T4 is switched according to the light emission control signal EM supplied to the light emission control line EML and supplies the driving voltage VDD supplied from the power line PL to the first thin film transistor T1.

The fifth thin film transistor T5 is switched according to the initialization signal INIT supplied to the third scan line SCL3 and supplies the initialization voltage Vinit supplied from the initialization line IL to the first thin film transistor T1.

The first capacitor C1 serves to maintain a data voltage supplied to the first thin film transistor T1 for one frame, and is provided between the gate electrode and the source electrode of the first thin film transistor T1.

The second capacitor C2 is provided between the source electrode and the drain electrode of the first thin film transistor T1.

The organic light emitting diode OLED emits predetermined light according to a data current supplied from the first thin film transistor T1.

As described above, one pixel of the display apparatus according to an embodiment of the present disclosure includes five thin film transistors T1 to T5 and two capacitors C1 and C2, but the present disclosure is not limited thereto. For example, one pixel of the display apparatus according to another embodiment of the present disclosure can include four or less thin film transistors, six or more thin film transistors, and the number of capacitors can be variously changed.

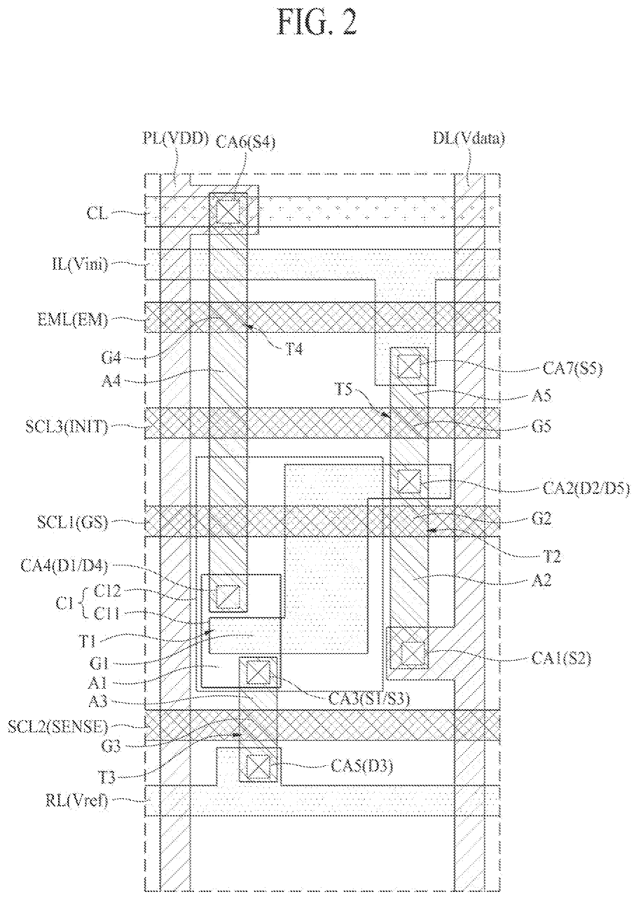

FIG. 2 is a plan view of one pixel provided in a display apparatus according to an embodiment of the present disclosure.

As shown in FIG. 2, a connection line CL, an initialization line IL, an emission control line EML, first to third scan lines SCL1, SCL2, SCL3, and a reference line RL are arranged in a first direction, for example, in a horizontal direction, and Power lines PL and data lines DL are arranged in a second direction different from the first direction, for example, in a vertical direction, and first to fifth thin film transistors T1, T2, T3, T4, T5 and first capacitors C1 are formed in a region between the power line PL and the data line DL

The connection line CL is connected to the power line PL so that a driving voltage VDD can be applied to a plurality of pixels. The power line PL may not be disposed adjacent to all pixels, but can be disposed adjacent to only some pixels, and thus a driving voltage VDD can be applied to a pixel not adjacent to the power line PL through the connection line CL.

An initialization voltage Vinit is applied to the initialization line IL, and an emission control signal EM is applied to the emission control line EML. A gate signal GS is applied to the first scan line SCL1, a sensing control signal SENSE is applied to the second scan line SCL2, and an initialization signal INIT is applied to the third scan line SCL3. A reference voltage Vref is applied to the reference line RL.

A driving voltage VDD is applied to the power line PL, and a data voltage Vdata is applied to the data line DL.

The planar arrangement structure and cross-sectional stacking positions of the connection line CL, the initialization line IL, the light emission control line EML, the first to third scan lines SCL1, SCL2, SCL3, the reference line RL, the power line PL, and the data line DL can be variously changed.

The first thin film transistor T1 includes a first gate electrode G1, a first active layer A1, a first source electrode S1, and a first drain electrode D1.

The first gate electrode G1 is electrically connected to the second drain electrode D2 of the second thin film transistor T2 in the second contact area CA2.

The first active layer A1 can include a semiconductor material, for example, an oxide semiconductor material. The oxide semiconductor material is, for example, an IZO (InZnO)-based oxide semiconductor material, an IGO (InGaO)-based oxide semiconductor material, an ITO (InSnO)-based oxide semiconductor material, an IGZO (InGaZnO)-based oxide material, an IGZTO (InGaZnSnO)-based oxide material, a GZTO (GaZnSnO)-base oxide semiconductor material, a GZO (GaZnO)-based oxide semiconductor material, an ITZO (InSnZnO)-based oxide semiconductor material, and a FIZO (FeInZnO)-based oxide semiconductor material.

The first source electrode S1 is electrically connected to the third source electrode S3 of the third thin film transistor T3 in the third contact area CA3, and the first drain electrode D1 is electrically connected to the fourth drain electrode D4 of the fourth thin film transistor T4 in the fourth contact area CA4.

The first source electrode S1 and the first drain electrode D1 are distinguished for convenience of description, and the first source electrode S1 and the first drain electrode D1 can be changed from each other. That is, the first source electrode S1 can become the first drain electrode D1, and the first drain electrode D1 can become the first source electrode S1. The same applies between the second to fifth source electrodes S2, S3, S4, S5 and the second to fifth drain electrodes D2, D3, D4, D5 to be described later.

One of the first source electrode S1 and the first drain electrode D1 is connected to one side of the first active layer A1, and the other is connected to the other side of the first active layer A1. For example, the first source electrode S1 can be connected to one side of the first active layer A1 in the third contact area CA3, and the first drain electrode D1 can be connected to the other side of the first active layer A1 in the fourth contact area CA4.

The second thin film transistor T2 includes a second gate electrode G2, a second active layer A2, a second source electrode S2, and a second drain electrode D2.

The second gate electrode G2 is connected to the first scan line SCL1. The second gate electrode G2 can protrude from the first scan line SCL1, or a portion of the first scan line SCL1 can function as the second gate electrode G2.

The second active layer A2 can include a semiconductor material, for example, an oxide semiconductor material. The oxide semiconductor material is, for example, an IZO (InZnO)-based oxide semiconductor material, an IGO (InGaO)-based oxide semiconductor material, an ITO (InSnO)-based oxide semiconductor material, an IGZO (InGaZnO)-based oxide semiconductor material, an IGZTO (InGaZnSnO)-based oxide semiconductor material, a GZTO (GaZnSnO)-base oxide semiconductor material, a GZO (GaZnO)-based oxide semiconductor material, an ITZO (InSnZnO)-based oxide semiconductor material, and a FIZO (FeInZnO)-based oxide semiconductor material. The third to fifth active layers A3, A4, and A5 described below can also be formed of the oxide semiconductor material as described above.

The second active layer A2 can be formed of the same oxide semiconductor material as the first active layer A1, but is not limited thereto, and can be formed of an oxide semiconductor material different from the first active layer A1. For example, each of the first active layer A1 and the second active layer A2 includes an oxide semiconductor material and can have different mobility. As a result, the first thin film transistor T1 and the second thin film transistor T2 can have different electrical characteristics.

According to an embodiment of the present disclosure, the first thin film transistor T1 and the second to fifth thin film transistors T2 to T5 can be designed to satisfy electrical characteristics required by the product, respectively. For example, if excellent stability is required for the first thin film transistor T1 as a driving thin film transistor and excellent current characteristics are required for the second to fifth thin film transistors T2-T5, the first active layer A1 can be made of an oxide semiconductor material having excellent stability, and the second to fifth active layers A2-A5 can be made of a semiconductor material with high mobility characteristics.

The second source electrode S2 is connected to the data line DL. The second source electrode S2 can protrude from the data line DL, or a portion of the data line DL can function as the second source electrode S2.

The second drain electrode D2 can be electrically connected to the first gate electrode G1 of the first thin film transistor T1 in the second contact area CA2, and can also be electrically connected to the fifth drain electrode D5 of the fifth thin film transistor T5.

The second source electrode S2 can be connected to one side of the second active layer A2 in the first contact area CA1, and the second drain electrode D2 can be connected to the other side of the second active layer A2 in the second contact area CA2.

The third thin film transistor T3 includes a third gate electrode G3, a third active layer A3, a third source electrode S3, and a third drain electrode D3.

The third gate electrode G3 is connected to the second scan line SCL2. The third gate electrode G3 can protrude from the second scan line SCL2, or a portion of the second scan line SCL2 can function as the third gate electrode G3.

The third source electrode S3 can be electrically connected to the first source electrode S1 of the first thin film transistor T1 in the third contact area CA3.

The third drain electrode D3 can be electrically connected to the reference line RL in the fifth contact area CA5.

The third source electrode S3 can be connected to one side of the third active layer A3 in the third contact area CA3, and the third drain electrode D3 can be connected to the other side of the third active layer A3 in the fifth contact area CA5.

The fourth thin film transistor T4 includes a fourth gate electrode G4, a fourth active layer A4, a fourth source electrode S4, and a fourth drain electrode D4.

The fourth gate electrode G4 is connected to the emission control line EML. The fourth gate electrode G4 can protrude from the emission control line EML, or a portion of the emission control line EML can function as the fourth gate electrode G4.

The fourth source electrode S4 can be electrically connected to the power line PL or the connection line CL in the sixth contact area CA6. A portion of the connection line CL can function as the fourth source electrode S4.

The fourth drain electrode D4 can be electrically connected to the first drain electrode D1 of the first thin film transistor T1 in the fourth contact area CA4.

The fourth source electrode S4 can be connected to one side of the fourth active layer A4 in the sixth contact area CA6, and the fourth drain electrode D4 can be connected to the other side of the fourth active layer A4 in the fourth contact area CA4.

The fifth thin film transistor T5 includes a fifth gate electrode G5, a fifth active layer A5, a fifth source electrode S5, and a fifth drain electrode D5.

The fifth gate electrode G5 is connected to the third scan line SCL3. The fifth gate electrode G5 can protrude from the third scan line SCL3, or a portion of the third scan line SCL3 can function as the fifth gate electrode G5.

The fifth source electrode S5 can be electrically connected to the initialization line IL in the seventh contact area CA7.

The fifth drain electrode D5 can be electrically connected to the second drain electrode D2 of the second thin film transistor T2 and the first gate electrode G1 of the first thin film transistor T1 in the second contact area CA2.

The fifth source electrode S5 can be connected to one side of the fifth active layer A5 in the seventh contact area CA7, and the fifth drain electrode D5 can be connected to the other side of the fifth active layer A5 in the second contact area CA2.

The first capacitor C1 includes a first capacitor electrode C11 and a second capacitor electrode C12. The first capacitor electrode C11 can be connected to the first gate electrode G1 of the first thin film transistor T1, and the first gate electrode G1 can function as the first capacitor electrode C11. The second capacitor electrode C12 can be disposed to have a larger area than the first capacitor electrode C11 under the first capacitor electrode C11, but is not limited thereto.

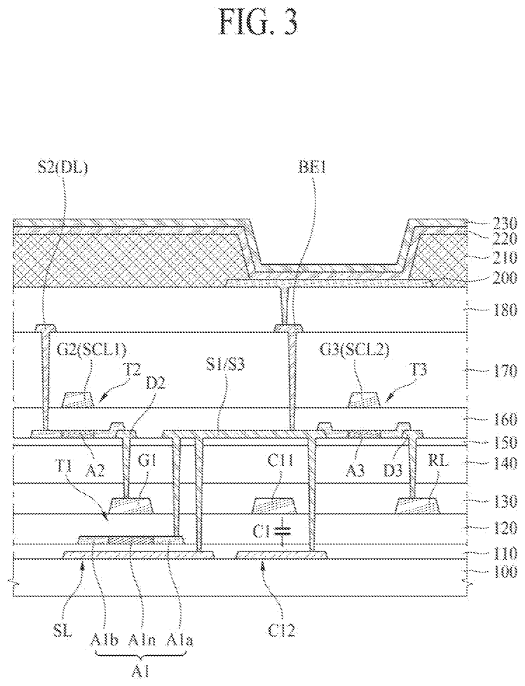

FIG. 3 is a schematic cross-sectional view of a display apparatus according to an embodiment of the present disclosure, which corresponds to cross-sections of the first thin film transistor T1, the second thin film transistor T2, and the third thin film transistor T3 in FIG. 2.

As shown in FIG. 3, the display apparatus according to an embodiment of this disclosure includes a substrate 100; first to eighth insulating layers 110, 120, 130, 140, 150, 160, 170, 180; a first thin film transistor including a first active layer A1, a first gate electrode G1, and a first source electrode S1; a second thin film transistor including a second active layer A2, a second gate electrode G2, a second source electrode S2 and a second drain electrode D2; a third thin film transistor including a third active layer A3, a third gate electrode G3, a third source electrode and a third drain electrode; a first capacitor C1 including a first capacitor electrode C11 and a second capacitor electrode C12; a first bridge electrode BE1, an anode electrode 200, a bank 210, a light emitting layer 220, and a cathode electrode 230.

The substrate 100 can be made of glass or plastic. In particular, the substrate 100 can be made of transparent plastic having flexible properties, for example, polyimide. When polyimide is used as the substrate 100, considering that a high-temperature deposition process is performed on the substrate 100, a heat-resistant polyimide capable of enduring high temperatures can be used.

A light shielding layer SL and a second capacitor electrode C12 of the first capacitor C1 are provided on the substrate 100.

The light shielding layer SL is provided to overlap the first active layer A1 of the first thin film transistor T1 to prevent external light from entering the first active layer A1. The light shielding layer SL can be electrically connected to the first active layer A1.

The second capacitor electrode C12 can be electrically connected to the light shielding layer SL and can be integrally formed with the light shielding layer SL. The second capacitor electrode C12 may be provided on a same layer as the light shielding layer SL. Accordingly, the second capacitor electrode C12 can be electrically connected to the first active layer A1.

The second capacitor electrode C12 and the light shielding layer SL can be formed of the same material (e.g., a metal or a metal conductive material) in the same layer through the same process.

A first insulating layer 110 is provided on the light shielding layer SL and the second capacitor electrode C12. The first insulating layer 110 can protect the first active layer A1 by blocking air and moisture. The first insulating layer 110 can be made of an inorganic insulating material, such as silicon oxide, silicon nitride, or metal oxide, but is not limited thereto and can be made of an organic insulating material. The first insulating layer 110 can be formed of a single layer or a plurality of layers.

The first active layer A1 is provided on the first insulating layer 110.

The first active layer A1 can include a channel part A1n, a first connection part A1a, and a second connection part A1b. The first connection part A1a can be connected to one side of the channel part A1n, and the second connection part A1b can be connected to the other side of the channel part A1n. The channel part A1n can be made of a semiconductor material and can overlap with the first gate electrode G1 to be protected by the first gate electrode G1. For example, the channel part A1n can be protected from both sides by being disposed between the first gate electrode G1 and the light shielding layer SL. The first connection part A1a and the second connection part A1b can have conductive characteristics by selectively conductorizing a semiconductor material. The first connection part A1a and the second connection part A1b may not overlap the first gate electrode G1. The first connection part A1a and the second connection part A1b have better conductivity than the channel part A1n, and each of them can serve as a wiring or a source/drain electrode.

Also, the second to fifth active layers A2 to A5 can include a channel part, a first connection part, and a second connection part in the same manner as the first active layer A1.

A second insulating layer 120 is provided on the first active layer A1. The second insulating layer 120 insulates the first active layer A1 from the first gate electrode G1. The second insulating layer 120 can include a single layer or a plurality of layers including an inorganic insulating material and/or an organic insulating material.

A first gate electrode G1 of the first thin film transistor T1, a first capacitor electrode C11 of the first capacitor C1, and a reference line RL are provided on the second insulating layer 120.

The first gate electrode G1 overlaps the first active layer A1, and the first capacitor electrode C11 overlaps the second capacitor electrode C12. The first gate electrode G1 can be connected to the first capacitor electrode C11, and the first gate electrode G1 and the first capacitor electrode C11 can be integrally formed.

The first gate electrode G1, the first capacitor electrode C11, and the reference line RL can be formed of the same material in the same layer through the same process.

A third insulating layer 130 is provided on the first gate electrode G1, the first capacitor electrode C11, and the reference line RL. The third insulating layer 130 can include a single layer or a plurality of layers including an inorganic insulating material and/or an organic insulating material.

A fourth insulating layer 140 is formed on the third insulating layer 130. The fourth insulating layer 140 can function as a planarization layer. The fourth insulating layer 140 can be composed of a single layer or multiple layers including an organic insulating material, but is not limited to it.

A fifth insulating layer 150 is formed on the fourth insulating layer 140. The fifth insulating layer 150 can include a single layer or a plurality of layers including an inorganic insulating material and/or an organic insulating material. The fifth insulating layer 150 can be thinner than the fourth insulating layer 140.

A first source electrode S1 of the first thin film transistor T1, a second drain electrode D2 of the second thin film transistor T2, a third source electrode S3 and a third drain electrode D3 of the third thin film transistor T3 are provided on the fifth insulating layer 150.

The first source electrode S1 of the first thin film transistor T1 is electrically connected to the first active layer A1, in particular, the first connection part A1a, and is also electrically connected to the light shielding layer SL and the second capacitor electrode C12. Specifically, the first source electrode S1 is electrically connected to the first connection part A1a of the first active layer A1 through a contact hole provided in the second to fifth insulating layers 120, 130, 140, and 150, and is electrically connected to the light shielding layer SL and the second capacitor electrode C12 through a contact hole provided in the first to fifth insulating layers 110, 120, 130, 140 and 150. Accordingly, the first source electrode S1 functions as a connection electrode electrically connecting between the first active layer A1 and the light shielding layer SL and between the first active layer A1 and the second capacitor electrode C12. In addition, the first source electrode S1 functions as a connection electrode connecting the first active layer A1 and the third active layer A3.

Also, a first drain electrode D1 electrically connected to the second connection part A1b of the first active layer A1 through a contact hole provided in the second to fifth insulating layers 120, 130, 140, and 150, and the first drain electrode D1 can also function as a connection electrode connecting between the first active layer A1 and the fourth active layer A4. The second to fifth source electrodes S2, S3, S4, S5 and the second to fifth drain electrodes D2, D3, D4, D5 described below can also function as connection electrodes.

The second drain electrode D2 of the second thin film transistor T2 can be electrically connected to the first gate electrode G1 through a contact hole provided in the third to fifth insulating layers 130, 140, and 150, thereby electrically connecting the second active layer A2 to the first gate electrode G1.

The third source electrode S3 of the third thin film transistor T3 can be integrally formed with the first source electrode S1. The third source electrode S3 can connect the third active layer A3 to the light shielding layer SL and the second capacitor electrode C12. In addition, the third source electrode S3 can connect the third active layer A3 and the first active layer A1.

The third drain electrode D3 of the third thin film transistor T3 is connected to the reference line RL through a contact hole provided in the third to fifth insulating layers 130, 140, and 150, and thus the third drain electrode D3 connects the second active layer A2 and the reference line RL.

A second active layer A2 is provided on the second drain electrode D2, and a third active layer A3 is provided on the third source electrode S3 and the third drain electrode D3.

A portion of a lower surface of the second active layer A2 is in direct contact with an upper surface and a side surface of the second drain electrode D2, and a portion of a lower surface of the third active layer A3 is in direct contact with an upper surface and a side surface of the third source electrode S3 and the third drain electrode D3. Specifically, one end or one side of the lower surface of the second active layer A2 is in direct contact with a portion of the upper surface and one side surface of the second drain electrode D2, one end of the third active layer A3 is in direct contact with the upper surface and one side surface of the third source electrode S3, and the other end of the third active layer A3 is in direct contact with a portion of the upper surface of the third drain electrode D3. One end of the second active layer A2 may be in contact with one side of the second drain electrode D2. Or, the second active layer A2 may be in contact with one side, upper surface and the other side of the second drain electrode D2.

Accordingly, according to an embodiment of present disclosure, the lower end surface of the second drain electrode D2 directly contacts the upper surface of the first gate electrode G1, and the side surface and the upper surface of the second drain electrode D2 directly contacts the lower surface of the second active layer A2, so that the second thin film transistor T2 and the first thin film transistor T1 can be electrically connected to each other by the one second drain electrode D2 extending into a contact hole provided in the third to fifth insulating layers 130, 140, and 150, thereby reducing the number of contact holes and the number of masks for pattern formation. For example, the first thin film transistor T1 can be positioned under the second thin film transistor T2 and the two transistors can be connected to each other via a single element, e.g., the second drain electrode D2, which can help save space, allowing pixels to be positioned closer together and improve resolution.

In addition, according to an embodiment of present disclosure, the lower end surface of the first source electrode S1 or the third source electrode S3 directly contacts the upper surface of the first active layer A1, and the side and upper surfaces of the first source electrode S1 or the third source electrode S3 are in direct contact with the lower surface of the third active layer A3, so that the third thin film transistor T3 and the first thin film transistor T1 can be electrically connected to each other by the first source electrode S1 or the third source electrode S3 extending into a contact hole provided in the second to fifth insulating layers 120, 130, 140, and 150, thereby reducing the number of contact holes and the number of masks for pattern formation. For example, in this way, one end of the first thin film transistor T1 can be directly connected to one end of the third thin film transistor T3 via a single element, e.g., the wiring element acting as both of the first source electrode S1/the third source electrode S3, which can help save space, allowing pixels to be positioned closer together and improve resolution.

A sixth insulating layer 160 is formed on the second active layer A2 and the third active layer A3. The sixth insulating layer 160 can include a single layer or a plurality of layers including an inorganic insulating material and/or an organic insulating material.

A second gate electrode G2 of the second thin film transistor T2 and a third gate electrode G3 of the third thin film transistor T3 are provided on the sixth insulating layer 160.

The second gate electrode G2 can be formed of a first scan line SCL1, and the third gate electrode G3 can be formed of a second scan line SCL2. The second gate electrode G2 and the third gate electrode G3 can be formed of the same material in the same layer through the same process.

A seventh insulating layer 170 is provided on the second gate electrode G2 and the third gate electrode G3. The seventh insulating layer 170 can include a single layer or a plurality of layers including an inorganic insulating material and/or an organic insulating material. The seventh insulating layer 170 can be thicker than the first to sixth insulating layers 110, 120, 130, 140, 150, 160 and the eighth insulation layer 180.

A second source electrode S2 of the second thin film transistor T2 and a first bridge electrode BE1 are provided on the seventh insulating layer 170.

The second source electrode S2 can be formed of a data line DL, or can be electrically connected to the second active layer A2 through a contact hole provided in the sixth and seventh insulating layers 160 and 170.

The first bridge electrode BE1 electrically connects the first source electrode S1 and the anode electrode 200. The first bridge electrode BE1 is electrically connected to the first source electrode S1 through a contact hole provided in the sixth and seventh insulating layers 160, 170. This contact hole may not overlap the third active layer A3 or may overlap the third active layer A3. In some situations, the first bridge electrode BE1 can be connected to a connection part of the third active layer A3, particularly the third active layer A3, which has excellent conductivity.

The second source electrode S2 and the first bridge electrode BE1 can be formed of the same material in the same layer through the same process.

An eighth insulating layer 180 is provided on the second source electrode S2 and the first bridge electrode BE1. The eighth insulating layer 180 can include a single layer or a plurality of layers including an inorganic insulating material and/or an organic insulating material.

An anode electrode 200 is provided on the eighth insulating layer 180.

The anode electrode 200 is connected to the first bridge electrode BE1 through a contact hole provided in the eighth insulating layer 180.

The bank 210 is provided to cover the edge of the anode electrode 200 to define a light emitting area. Accordingly, an upper surface area of the anode electrode 200 exposed without being covered by the bank 210 becomes a light emitting area.

The light emitting layer 220 is provided on the anode electrode 200 and the bank 210. The light emitting layer 220 can include red, green, and blue light emitting layers patterned for each pixel, or can be formed of a white light emitting layer connected from all pixels. When the emission layer 220 is formed of a white emission layer, the emission layer 220 can include, for example, a first stack including a blue emission layer, a second stack including a yellow green emission layer, and a charge generation layer provided between the first stack and the second stack, but is not limited thereto.

The cathode electrode 230 is provided on the light emitting layer 220.

Also, an encapsulation layer for preventing moisture or oxygen from penetrating can be additionally formed on the cathode electrode 230.

As described above, according to an embodiment of the present disclosure, the first thin film transistor T1 is disposed close to the substrate 100, and the second thin film transistor T2 and the third thin film transistor T3 are disposed far above the substrate 100, so that it is possible to more easily arrange multiple thin film transistors within one pixel, thereby reducing the size of the pixel and improving the resolution of the display device.

In particular, when the third thin film transistor T3 includes a third active layer A3 having high mobility characteristics, the third active layer A3 is directly connected to the third source electrode S3 and the third drain electrode D3 provided below it, so that the heat treatment process when the third source electrode S3 and the third drain electrode D3 are formed does not affect the third active layer A3, and thus high mobility characteristics of the third active layer A3 can be prevented from being degraded. In other words, the third active layer A3 can be formed after and on top of portions of the third source electrode S3 and the third drain electrode D3, so that the third active layer A3 is not at all affected by an earlier heat treatment process used for the third source electrode S3 and the third drain electrode D3.

In addition, when the second thin film transistor T2 includes the second active layer A2 with high mobility characteristics, the second active layer A2 is directly connected to the second drain electrode D2 provided below it, so that the heat treatment process when the second drain electrode D2 is formed does not affect the second active layer A2 and thus the second active layer A2 can be prevented from being degraded. In other words, the second active layer A2 is formed after the second drain electrode D2 is formed, and the second active layer A2 can be formed to overlap at least a portion of the second drain electrode D2.

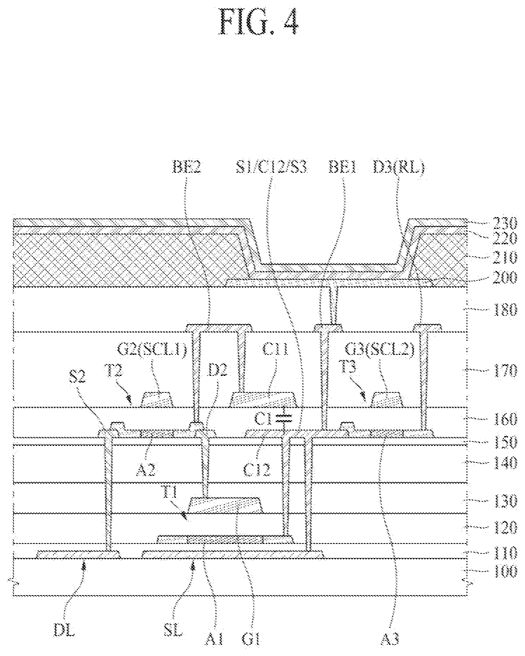

FIG. 4 is a schematic cross-sectional view of a display apparatus according to another embodiment of the present disclosure, which corresponds to cross-sections of the first thin film transistor T1, the second thin film transistor T2, and the third thin film transistor T3 in FIG. 2.

As shown in FIG. 4, the display apparatus according to an embodiment of this disclosure includes a substrate 100; first to eighth insulating layers 110, 120, 130, 140, 150, 160, 170, 180; a first thin film transistor including a first active layer A1, a first gate electrode G1, and a first source electrode S1; a second thin film transistor including a second active layer A2, a second gate G2, a second source electrode S2 and a second drain electrode D2; a third thin film transistor including a third active layer A3, a third gate electrode G3, a third source electrode S3 and a third drain electrode D3; a first capacitor including a first capacitor electrode C11 and a second capacitor electrode C12; a first bridge electrode BEL a second bridge electrode BE2; an anode electrode 200; a bank 210; a light emitting layer 220; and a cathode electrode 230.

Hereinafter, repeated descriptions of the same configuration as in FIG. 3 will be omitted.

A data line DL and a light shielding layer SL are provided on the substrate 100.

The data line DL and the light shielding layer SL can be formed of the same material in the same layer through the same process.

A first insulating layer 110 is provided on the data line DL and the light shielding layer SL, and the first active layer A1 is provided on the first insulating layer 110.

A second insulating layer 120 is provided on the first active layer A1, and a first gate electrode G1 of the first thin film transistor T1 is provided on the second insulating layer 120.

A third insulating layer 130 is provided on the first gate electrode G1, a fourth insulating layer 140 is provided on the third insulating layer 130, and a fifth insulating layer 150 is provided on the fourth insulating layer 140.

A first source electrode S1 of the first thin film transistor T1, a second source electrode S2 and a second drain electrode D2 of the second thin film transistor T2, a third source electrode S3 of the third thin film transistor T3, and a second capacitor electrode C12 are provided on the fifth insulating layer 150.

The first source electrode S1 of the first thin film transistor T1 is electrically connected to the first active layer A1 through a contact hole provided in the second to fifth insulating layers 120, 130, 140, and 150, and electrically connected to the light shielding layer SL through a contact hole provided in the first to fifth insulating layers 110, 120, 130, 140, and 150. The first source electrode S1 can connect the first active layer A1 to the light shielding layer SL, and can also connect the first active layer A1 to the second active layer A2.

The second source electrode S2 of the second thin film transistor T2 is electrically connected to the data line DL through a contact hole provided in the first to fifth insulating layers 110, 120, 130, 140, and 150. The second drain electrode D2 of the second thin film transistor T2 is electrically connected to the first gate electrode G1 through a contact hole provided in the third to fifth insulating layers 130, 140, and 150.

The third source electrode S3 of the third thin film transistor T3 can be integrally formed with the first source electrode S1 and the second capacitor electrode C12. The third source electrode S3 can connect the third active layer A3 to the light shielding layer SL. In addition, the third source electrode S3 can connect the third active layer A3 to the first active layer A1.

The first source electrode S1, the second source electrode S2, the second drain electrode D2, the third source electrode S3, and the second capacitor electrode C12 can be formed of the same material in the same layer through the same process.

A second active layer A2 is provided on the second source electrode S2 and the second drain electrode D2, and a third active layer A3 is provided on the third source electrode S3.

A portion of a lower surface of the second active layer A2 is in direct contact with an upper surface and a side surface of the second source electrode S2 and the second drain electrode D2, and a portion of a lower surface of the third active layer A3 is in direct contact with an upper surface and a side surface of the third source electrode S3.

Specifically, one end of the lower surface of the second active layer A2 is in direct contact with a portion of the upper surface and one side surface of the second source electrode S2, and the other end of the lower surface of the second active layer A2 is in direct contact with a portion of the upper surface and one side surface of the second drain electrode D2. In addition, an end of one side of the lower surface of the third active layer A3 is in direct contact with a portion of the upper surface and one side surface of the third source electrode S3.

Therefore, according to another embodiment of the present disclosure, the lower end surface of the second drain electrode D2 contacts the upper surface of the first gate electrode G1, and the side surface and the upper surface of the second drain electrode D2 contacts the lower surface of the second active layer A2, so that the second thin film transistor T2 and the first thin film transistor T1 can be electrically connected to each other by the one second drain electrode D2 extending into a contact hole provided in the third to fifth insulating layers 130, 140, and 150, thereby reducing the number of contact holes and the number of masks for pattern formation. In other words, the first transistor T1 can be connected to the second thin film transistor T2 via one element, e.g., the second drain electrode D2, which can save space and reduce the number of contact holes needed to connect circuit elements together.

In addition, according to an embodiment of present disclosure, the lower end surface of the first source electrode S1 or the third source electrode S3 contacts the upper surface of the first active layer A1, and the side and upper surfaces of the first source electrode S1 or the third source electrode S3 are in contact with the lower surface of the third active layer A3, so that the third thin film transistor T3 and the first thin film transistor T1 can be electrically connected to each other by the first source electrode S1 or the third source electrode S3 extending into the contact holes provided in the second to fifth insulating layers 120, 130, 140, and 150, thereby reducing the number of contact holes and the number of masks for pattern formation. For example, the first source electrode S1, the third source electrode S3 and the second capacitor electrode C12 can integrally formed and share a common piece of wiring, which can save space.

A sixth insulating layer 160 is formed on the second active layer A2 and the third active layer A3, and the second capacitor electrode C12. Also, a second gate electrode G2 of the second thin film transistor T2, a first capacitor electrode C11, and a third gate electrode G3 of the third thin film transistor T3 are provided on the sixth insulating layer 160. The second gate electrode G2, the first capacitor electrode C11, and the third gate electrode G3 can be formed of the same material on the same layer through the same process.

A seventh insulating layer 170 is provided on the second gate electrode G2, the first capacitor electrode C11, and the third gate electrode G3. Also, the first bridge electrode BE1, the second bridge electrode BE2, and the third drain electrode D3 of the third thin film transistor T3 are provided on the seventh insulating layer 170.

The first bridge electrode BE1 electrically connects the first source electrode S1 and the anode electrode 200. The first bridge electrode BE1 is electrically connected to the first source electrode S1 through a contact hole provided in the sixth and seventh insulating layers 160, 170. In some situations, the first bridge electrode BE1 can be connected to the third active layer A3, particularly, a connection part of the third active layer A3 having excellent conductivity.

The second bridge electrode BE2 serves to electrically connect the first gate electrode G1 and the first capacitor electrode C11, and is connected to the second active layer A2, particularly, a connection part having excellent conductivity, through a contact hole provided in the sixth and seventh insulating layers 160 and 170. Accordingly, the first capacitor electrode C11 is electrically connected to the first gate electrode G1 via the second bridge electrode BE2, the second active layer A2, and the second drain electrode D2. In some situations, the second bridge electrode BE2 can be connected to the second drain electrode D2 through a contact hole provided in the sixth and seventh insulating layers 160, 170.

The third drain electrode D3 is connected to the third active layer A3 through a contact hole provided in the sixth and seventh insulating layers 160, 170. The third drain electrode D3 can be formed of a reference line RL.

The first bridge electrode BE1, the second bridge electrode BE2, and the third drain electrode D3 can be formed of the same material on the same layer through the same process.

An eighth insulating layer 180 is provided on the first bridge electrode BE1, the second bridge electrode BE2, and the third drain electrode D3, and an anode electrode 200 is provided on the eighth insulating layer 180. The anode electrode 200 is connected to the first bridge electrode BE1 through a contact hole provided in the eighth insulating layer 180.

The bank 210 is provided to cover an edge of the anode electrode 200, the light emitting layer 220 is provided on the anode electrode 200 and the bank 210, and the cathode electrode 230 is provided on the light emitting layer 200.

As described above, according to another embodiment of the present disclosure, the first thin film transistor T1 is disposed close to the substrate 100, and the second thin film transistor T2 and the third thin film transistor T3 are disposed far above the substrate 100, so that it is possible to more easily arrange multiple thin film transistors within one pixel, thereby reducing the size of the pixel and improving the resolution of the display device.

In particular, when the second thin film transistor T2 includes a second active layer A2 having high mobility characteristics, the second active layer A2 is directly connected to the second source electrode S2 and the second drain electrode D2 provided below it, so that the heat treatment process when the second source electrode S2 and the second drain electrode D2 are formed does not affect the second active layer A2, and thus high mobility characteristics of the second active layer A2 can be prevented from being degraded. For example, the active layer A2 can be formed after and on top of the second source electrode S2 and the second drain electrode D2, thus, protecting the second active layer A2 of the second thin film transistor T2 from any heat issues that arise during formation of the second source electrode S2 and the second drain electrode D2.

In addition, when the third thin film transistor T3 includes the third active layer A3 with high mobility characteristics, the third active layer A3 is directly connected to the third source electrode S3 provided below it, so that the heat treatment process when the third source electrode S3 is formed does not affect the third active layer A3 and thus the third active layer A3 can be prevented from being degraded. For example, the third active layer A3 can be formed after and on top of the third source electrode S3. Also, the first source electrode S1, the second capacitor electrode C12 and the third source electrode S3 can be integrally formed of a same piece of wiring.

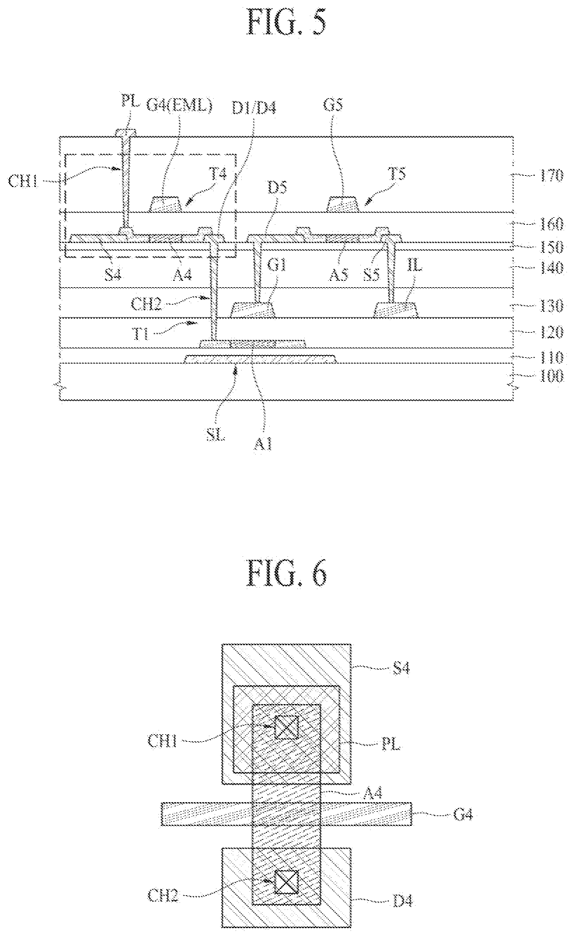

FIG. 5 is a schematic cross-sectional view of a display apparatus according to an embodiment of the present disclosure, which corresponds to cross-sections of the first thin film transistor T1, the fourth thin film transistor T4, and the fifth thin film transistor T5 in FIG. 2.

As shown in FIG. 5, the display apparatus according to an embodiment of present disclosure includes a substrate 100; first to seventh insulating layers 110, 120, 130, 140, 150, 160, 170; a first thin film transistor T1 including a first active layer A1, a gate electrode G1 and a first drain electrode D1; a fourth thin film transistor T4 including a fourth active layer A4, a fourth gate electrode G4, a fourth source electrode S4 and a fourth drain electrode D4; a fifth thin film transistor T5 including a fifth gate electrode G5, a fifth source electrode S5 and a fifth drain electrode D5.

Hereinafter, repeated descriptions of the same configuration as those of the above-described embodiments will be omitted.

A light shielding layer SL is provided on the substrate 100, a first insulating layer 110 is provided on the light shielding layer SL, and the first active layer A1 is provided on the first insulating layer 110.

A second insulating layer 120 is provided on the first active layer A1, and a first gate electrode G1 of the first thin film transistor T1 and an initialization line IL are provided on the second insulating layer 120. The first gate electrode G1 and the initialization line IL can be formed of the same material on the same layer through the same process.

A third insulating layer 130 is provided on the first gate electrode G1 and the initialization line IL, a fourth insulating layer 140 is provided on the third insulating layer 130, and a fifth insulating layer 150 is provided on the fourth insulating layer 140.

A first drain electrode D1 of the first thin film transistor T1, a fourth source electrode S4 and a fourth drain electrode D4 of the fourth thin film transistor T4, and a fifth source electrode S5 and a fifth drain electrode D5 of the fifth thin film transistor T5 are provided on the fifth insulating layer 150. The fifth insulating layer 150 can be thinner than the first to fourth, sixth and seventh insulating layers 110, 120, 130, 140, 160, 170.

The first drain electrode D1 of the first thin film transistor T1 is electrically connected to the first active layer A1 through a second contact hole CH2 provided in the second to fifth insulating layers 120, 130, 140, and 150.

The fourth drain electrode D4 of the fourth thin film transistor T4 is integrally formed with the first drain electrode D1 and extends through the second contact hole CH2 provided in the first to fifth insulating layers 110, 120, 130, 140, and 150.

The fifth drain electrode D5 of the fifth thin film transistor T5 is electrically connected to the first gate electrode G1 through a contact hole provided in the third to fifth insulating layers 130, 140, and 150. The fifth source electrode S5 of the fifth thin film transistor T5 is electrically connected to the initialization line IL through a contact hole provided in the third to fifth insulating layers 130, 140, and 150.

The first drain electrode D1, the fourth source electrode S4, the fourth drain electrode D4, the fifth source electrode S5, and the fifth drain electrode D5 can be formed of the same material in the same layer through the same process.

A fourth active layer A4 is provided on the fourth source electrode S4 and the fourth drain electrode D4, and a fifth active layer A5 is provided on the fifth source electrode S5 and the fifth drain electrode D5.

A portion of the lower surface of the fourth active layer A4 is in direct contact with the upper and side surfaces of the fourth source electrode S4 and the fourth drain electrode D4. In particular, one end of the lower surface of the fourth active layer A4 contacts a portion of the upper surface and one side surface of the fourth source electrode S4, and the other end of the lower surface of the fourth active layer A4 contacts a portion of the upper surface and one side surface of the upper surface of the fourth drain electrode D4.

A portion of the lower surface of the fifth active layer A5 is in direct contact with the upper and side surfaces of the fifth source electrode S5 and the fifth drain electrode D5. Particularly, one end of the lower surface of the fifth active layer A5 contacts a portion of the upper surface and one side surface of the fifth source electrode S5, and the other end of the lower surface of the fifth active layer A5 contacts a portion of the upper surface and one side surface of the fifth drain electrode D5.

Therefore, according to another embodiment of present disclosure, the lower end surfaces of the first or fourth drain electrode D1 or D4 are in contact with the upper surface of the first active layer A1, and the side surfaces and upper surfaces of the first or fourth drain electrode D1 or D4 are in contact with the lower surface of the fourth active layer A4, so that the fourth thin film transistor T4 and the first thin film transistor T1 can be electrically connected to each other by the first drain electrode D1 or the fourth drain electrode D4 extending into a contact hole provided in the second to fifth insulating layers 120, 130, 140, and 150, reducing the number of contact holes and the number of masks for pattern formation. Also, the first and fourth drain electrode D1 and D4 can be integrally formed of a same piece of wiring.

In addition, according to another embodiment of the present disclosure, the lower end surface of the fifth drain electrode D5 contacts the upper surface of the first gate electrode G1, and the side surface and the upper surface of the fifth drain electrode D5 contacts the lower surface of the fifth active layer A5, so that the fifth thin film transistor T5 and the first thin film transistor T1 can be electrically connected to each other by the fifth drain electrode D5 extending into a contact hole provided in the third to fifth insulating layers 130, 140, 150, reducing the number of contact holes and the number of masks for pattern formation.

A sixth insulating layer 160 is formed on the fourth active layer A4 and the fifth active layer A5, and a fourth gate electrode G4 of the fourth thin film transistor T4 and a fifth gate electrode G5 of the fifth thin film transistor T5 are provided on the sixth insulating layer 160.

The fourth gate electrode G4 can be formed of an emission control line EML, and the fifth gate electrode G5 can be formed of a third scan line SCL3. The fourth gate electrode G4 and the fifth gate electrode G5 can be formed of the same material in the same layer through the same process.

A seventh insulating layer 170 is provided on the fourth gate electrode G4 and the fifth gate electrode G5, and a power line PL is provided on the seventh insulating layer 170.

The power line PL is electrically connected to the fourth active layer A4, particularly, a connection part having excellent conductivity, through a first contact hole CH1 provided in the sixth to seventh insulating layers 160 and 170.

As described above, according to another embodiment of the present disclosure, the first thin film transistor T1 is disposed close to the substrate 100, and the fourth thin film transistor T4 and the fifth thin film transistor T5 are disposed far above the substrate 100, so that it is possible to more easily arrange multiple thin film transistors within one pixel, thereby reducing the size of the pixel and improving the resolution of the display device.

In particular, when the fourth thin film transistor T4 includes a fourth active layer A4 having high mobility characteristics, the fourth active layer A4 is directly connected to the fourth source electrode S4 and the fourth drain electrode D4 provided below it, so that the heat treatment process when the fourth source electrode S4 and the fourth drain electrode D4 are formed does not affect the fourth active layer A4, and thus high mobility characteristics of the fourth active layer A4 can be prevented from being degraded. For example, the fourth active layer A4 can be formed after and on top of the fourth source electrode S4 and the fourth drain electrode D4.

In addition, when the fifth thin film transistor T5 includes the fifth active layer A5 with high mobility characteristics, the fifth active layer A5 is directly connected to the fifth source electrode S5 and the fifth drain electrode D5 provided below it, so that the heat treatment process when the fifth source electrode S5 and the fifth drain electrode is formed does not affect the fifth active layer A5 and thus the fifth active layer A5 can be prevented from being degraded. For example, the fifth active layer A5 can be formed after and on top of the fifth source electrode S5 and the fifth drain electrode D5.

FIG. 6 is a schematic plan view of a display apparatus according to an embodiment of the present disclosure, which is a plan view of a rectangular dotted line region, that is, a fourth thin film transistor T4, in FIG. 5.

As shown in FIG. 6, the fourth gate electrode G4 is extended in the horizontal direction, and a fourth source electrode S4 is provided on one side of the fourth gate electrode G4, for example, on an upper side, and a fourth drain electrode D4 is provided on the other side of the fourth gate electrode G4, for example, on the lower side, and the fourth active layer A4 is provided to extend in the vertical direction and overlap with the fourth gate electrode G4, the fourth source electrode S4, and the fourth drain electrode D4.

In this situation, the power line PL is formed to overlap the fourth source electrode S4 and the fourth active layer A4. The first contact hole CH1 is formed to overlap with the power line PL, the fourth source electrode S4, and the fourth active layer A4. The power line PL and the fourth active layer A4 are connected to each other through the first contact hole CH1.

In addition, the second contact hole CH2 is formed to overlap the fourth drain electrode D4 and the fourth active layer A4.

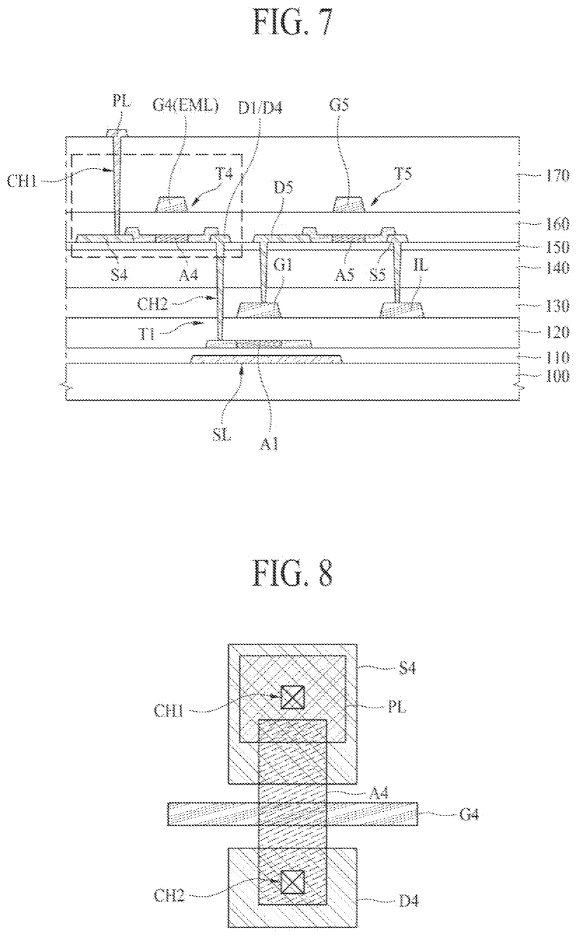

FIG. 7 is a schematic cross-sectional view of a display apparatus according to another embodiment of the present disclosure, which corresponds to cross-sections of the first thin film transistor T1, the fourth thin film transistor T4, and the fifth thin film transistor T5 in FIG. 2.

FIG. 7 is the same as FIG. 5 except that a connection structure of the power line PL is changed (e.g., PL is moved to be connected to S4 rather than A4), and thus, the same reference numerals are applied to the same configuration, and only different configurations will be described below.

As shown in FIG. 7, the power line PL is connected to the fourth source electrode S4 through a first contact hole CH1 provided in the sixth and seventh insulating layers 160 and 170.

That is, in FIG. 5, the power line PL contacts with the fourth active layer A4, while in FIG. 7, the power line PL contacts with the fourth source electrode S4.

FIG. 8 is a schematic plan view of a display apparatus according to an embodiment of the present disclosure, which is a plan view of a rectangular dotted line region, that is, a fourth thin film transistor T4, in FIG. 7.

FIG. 8 is the same as FIG. 6 except that the position of the power line PL is changed, and thus, the same reference numerals are applied to the same configuration, and only different configurations will be described below.

As shown in FIG. 8, the power line PL is formed to overlap the fourth source electrode S4 and the fourth active layer A4. In some situations, the power line PL can overlap the fourth source electrode S4, but may not overlap the fourth active layer A4.

The first contact hole CH1 overlaps with the power line PL and the fourth source electrode S4, but does not overlap the fourth active layer A4. Accordingly, the power line PL and the fourth source electrode S4 are connected to each other through the first contact hole CH1.

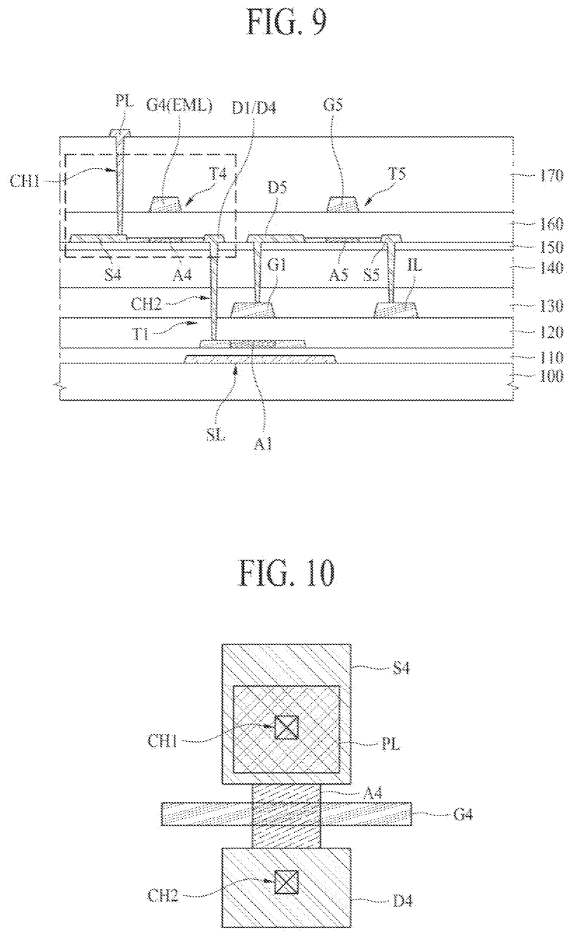

FIG. 9 is a schematic cross-sectional view of a display apparatus according to another embodiment of the present disclosure, which corresponds to cross-sections of the first thin film transistor T1, the fourth thin film transistor T4, and the fifth thin film transistor T5 in FIG. 2.

FIG. 9 is the same as FIG. 5 except that the connection structure of the power line PL, the structure of the fourth active layer A4, and the structure of the fifth active layer A5 are changed, and thus the same reference numerals are assigned to the same configuration, and only different configurations will be described below. For example, the power line PL is moved, and the fourth and fifth active layers A4, A5 are thinner and do not overlap with their corresponding source and drain electrodes.

As shown in FIG. 9, the power line PL is connected to the fourth source electrode S4 through a first contact hole CH1 provided in the sixth and seventh insulating layers 160 and 170. That is, in FIG. 5, the power line PL contacts the fourth active layer A4, while in FIG. 9, the power line PL contacts the fourth source electrode S4.

Also, the fourth active layer A4 is in contact with one side of the fourth source electrode S4 and one side of the fourth drain electrode D4, and is not in contact with the upper surface of the fourth source electrode S4 and the upper surface of the fourth drain electrode D4.

In addition, the fifth active layer A5 is in contact with one side of the fifth source electrode S5 and one side of the fifth drain electrode D5, and is not in contact with the upper surface of the fifth source electrode S5 and the upper surface of the fifth drain electrode D5.

FIG. 10 is a schematic plan view of a display apparatus according to another embodiment of the present disclosure, which is a plan view of a rectangular dotted line region, that is, a fourth thin film transistor T4, in FIG. 9.

Hereinafter, only a configuration different from that of FIG. 6 will be described.

As shown in FIG. 10, the fourth active layer A4 contacts one end of the fourth source electrode S4 and one end of the fourth drain electrode D4, respectively, and does not overlap the fourth source electrode S4 and the fourth drain electrode D4.

The power line PL overlaps the fourth source electrode S4, but does not overlap the fourth active layer A4.

The first contact hole CH1 overlaps the power line PL and the fourth source electrode S4, but does not overlap the fourth active layer A4. Accordingly, the power line PL and the fourth source electrode S4 are connected through the first contact hole CH1.

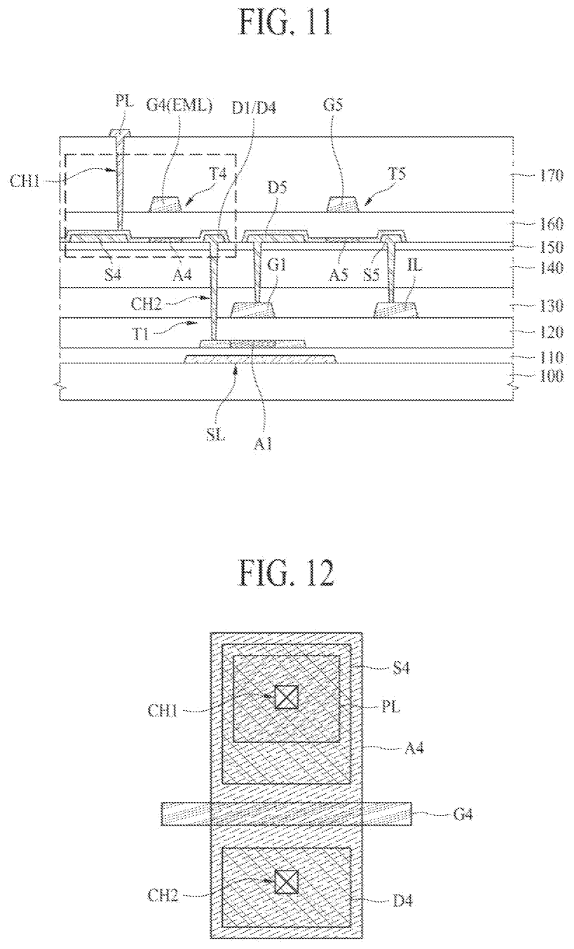

FIG. 11 is a schematic cross-sectional view of a display apparatus according to another embodiment of the present disclosure, which corresponds to cross-sections of the first thin film transistor T1, the fourth thin film transistor T4, and the fifth thin film transistor T5 in FIG. 2.

FIG. 11 is the same as FIG. 5 except that the structure of the fourth active layer A4 and the structure of the fifth active layer A5 are changed, and thus the same reference numerals are applied to the same configuration, and only different configurations will be described below. For example, the fourth and fifth active layers A4 are extended to completely overlap with and cover their corresponding source and drain electrodes.

As shown in FIG. 11, the fourth active layer A4 contacts one side surface, the other side surface, and the entire upper surface of the fourth source electrode S4, and also contacts one side surface, the other side surface, and the entire upper surface of the fourth drain electrode D4.

In addition, the fifth active layer A5 contacts one side, the other side, and the entire upper surface of the fifth source electrode S5, and also contacts one side, the other side, and the entire upper surface of the fifth drain electrode D5.

FIG. 12 is a schematic plan view of a display apparatus according to another embodiment of the present disclosure, which is a plan view of a rectangular dotted line region, that is, a fourth thin film transistor T4, in FIG. 11. Hereinafter, only a configuration different from that of FIG. 6 will be described.

As shown in FIG. 12, the fourth active layer A4 is formed to overlap with the entire fourth source electrode S4 and the entire fourth drain electrode D4.

The power line PL is formed to overlap the fourth source electrode S4 and the fourth active layer A4.

The first contact hole CH1 is formed to overlap the power line PL, the fourth source electrode S4, and the fourth active layer A4. The power line PL and the fourth active layer A4 are connected through the first contact hole CH1.

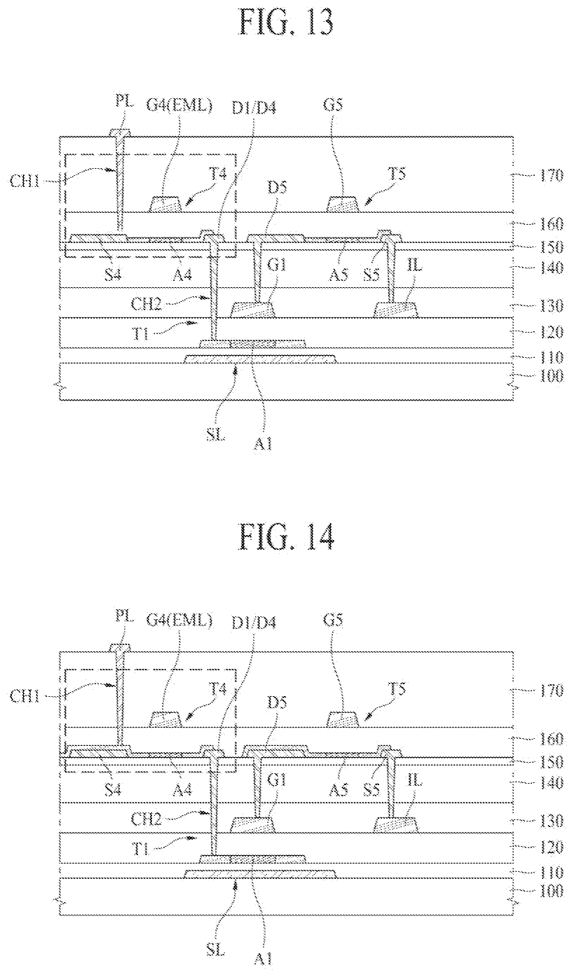

FIG. 13 is a schematic cross-sectional view of a display apparatus according to another embodiment of the present disclosure, which corresponds to cross-sections of the first thin film transistor T1, the fourth thin film transistor T4, and the fifth thin film transistor T5 in FIG. 2. For example, the fourth and fifth active layers A4 and A5 only overlap a portion of one of the corresponding source or drain electrodes, while the other electrode is not overlapped by the active layer, and the fourth and fifth active layers A4 can be thinner than their corresponding source and drain electrodes.

FIG. 13 is the same as FIG. 5 except that the connection structure of the power line PL, the structure of the fourth active layer A4, and the structure of the fifth active layer A5 are changed, and thus the same reference numerals are applied to the same configuration, and only different configurations will be described below.

As shown in FIG. 13, the power line PL contacts the fourth source electrode S4.

The fourth active layer A4 is in contact with one side surface of the fourth source electrode S4, and is not in contact with the upper surface of the fourth source electrode S4. However, the fourth active layer A4 is in contact with one side surface and a portion of the upper surface of the fourth drain electrode D4.

In addition, the fifth active layer A5 is in contact with one side surface of the fifth drain electrode D5, and is not in contact with the upper surface of the fifth drain electrode D5. However, the fifth active layer A5 is in contact with one side surface and a portion of the upper surface of the fifth source electrode S5.

FIG. 14 is a schematic cross-sectional view of a display apparatus according to another embodiment of the present disclosure, which corresponds to cross-sections of the first thin film transistor T1, the fourth thin film transistor T4, and the fifth thin film transistor T5 in FIG. 2.

FIG. 14 is the same as FIG. 5 except that the structure of the fourth active layer A4 and the structure of the fifth active layer A5 are changed, and thus the same reference numerals are applied to the same configuration, and only different configurations will be described below. For example, the fourth and fifth active layers A4 and A5 entirely overlap one of the corresponding source or drain electrodes, while the other electrode is only partially overlapped by the corresponding active layer.

As shown in FIG. 14, the fourth active layer A4 contacts one side surface, the other side surface, and the entire upper surface of the fourth source electrode S4. However, the fourth active layer A4 is in contact with one side surface and a portion of the upper surface of the fourth drain electrode D4.

In addition, the fifth active layer A5 is in contact with one side surface, the other side surface, and the entire upper surface of the fifth drain electrode D5. However, the fifth active layer A5 is in contact with one side surface and a portion of the upper surface of the fifth source electrode S5.

As shown in FIGS. 13 and 14, one side of the fourth active layer A4 can contact the fourth drain electrode D4, the other side of the fourth active layer A4 can contact the fourth source electrode S4, and an overlapping structure between one side of the fourth active layer A4 and the fourth drain electrode D4 can differ to an overlapping structure between the other side of the fourth active layer A4 and the fourth source electrode S4.

FIGS. 5 to 14 are the first thin film transistor T1, the fourth thin film transistor T4, and the fifth thin film transistor T5, and various structures according to FIGS. 5 to 14 can be applied to the first thin film transistor T1, the second thin film transistor T2, and the third thin film transistor T3.

For example, the structure between the fourth active layer A4 and the fourth source/drain electrode S4/D4 according to FIGS. 5 to 14 can be applied to the structure between the second active layer A2 and the second source/drain electrode S2/D2 and between the third active layer A3 and the third source/drain electrode S3/D3.

In addition, the structure between the fourth active layer A4, the fourth source electrode S4, and the power line PL according to FIGS. 5 to 14 can be applied to the structure between the third active layer A3, the third source electrode S3, and the first bridge electrode BE1 in FIGS. 3 and 4, or between the second active layer A2, the second drain electrode 2D and the second bridge electrode BE2 in FIG. 4.

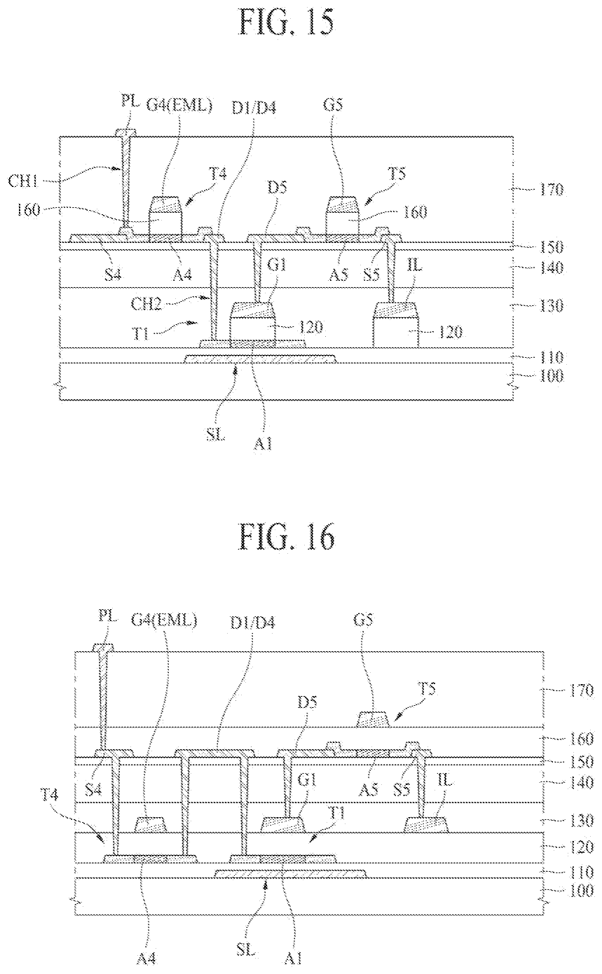

FIG. 15 is a schematic cross-sectional view of a display apparatus according to another embodiment of the present disclosure, which corresponds to cross-sections of the first thin film transistor T1, the fourth thin film transistor T4, and the fifth thin film transistor T5 in FIG. 2.

FIG. 15 is the same as FIG. 5 except that structures of the second insulating layer 120 and the sixth insulating layer 160 are changed, and thus, the same reference numerals are applied to the same configuration, and only different configurations will be described below.

As shown in FIG. 15, the second insulating layer 120 is a gate insulating layer, and is formed between the first active layer A1 and the first gate electrode G1 in the same pattern as the first gate electrode G1. In addition, the second insulating layer 120 is formed in the same pattern as the initialization line IL under the initialization line IL.

The second insulating layer 120 can be formed on the entire surface of the substrate 100 and then etched using the first gate electrode G1 and the initialization line IL as masks to have the same pattern as the first gate electrode G1 and the initialization line IL. An area of the first active layer A1 overlapping the second insulating layer 120 can form a channel portion, and an area of the first active layer A1 not overlapping the second insulating layer 120 can form a connection portion.

The sixth insulating layer 160 is also a gate insulating layer, and is formed in the same pattern as the fourth gate electrode G4 between the fourth active layer A4 and the fourth gate electrode G4. In addition, the sixth insulating layer 160 has the same pattern as the fifth gate electrode G5 between the fifth active layer A5 and the fifth gate electrode G5. The sixth insulating layer 160 can be formed on the entire surface of the substrate 100 and then etched using the fourth gate electrode G4 and the fifth gate electrode G5 as masks to have the same pattern as the fourth gate electrode G4 and the fifth gate electrode G5.

The structures of the second insulating layer 120 and the sixth insulating layer 160 according to FIG. 15 can be equally applied to and are combinable with the above-described various embodiments.

FIG. 16 is a schematic cross-sectional view of a display apparatus according to another embodiment of the present disclosure, which corresponds to cross-sections of the first thin film transistor T1, the fourth thin film transistor T4, and the fifth thin film transistor T5 in FIG. 2.

FIG. 16 is different from FIG. 5 described above in that the fourth thin film transistor T4 is disposed at the same position as the first thin film transistor T1, e.g., near the substrate 100.

As shown in FIG. 16, a light shielding layer SL is provided on a substrate 100, a first insulating layer 110 is provided on the light shielding layer SL, and a first active layer A1 and a fourth active layer A4 are provided on the first insulating layer 110. The first active layer A1 and the fourth active layer A4 can be formed of the same material in the same layer through the same process.

A second insulating layer 120 is provided on the first active layer A1 and the fourth active layer A4, and a first gate electrode G1 of the first thin film transistor T1, a fourth gate electrode G4 of the fourth thin film transistor T4, and an initialization line IL are provided on the second insulating layer 120. The first gate electrode G1, the fourth gate electrode G4, and the initialization line IL can be formed of the same material on the same layer through the same process.

A third insulating layer 130 is provided on the first gate electrode G1, the fourth gate electrode G4, and the initialization line IL, a fourth insulating layer 140 is provided on the third insulating layer 130, and a fifth insulating layer 150 is provided on the fourth insulating layer 140.

A first drain electrode D1 of the first thin film transistor T1, a fourth source electrode S4 and a fourth drain electrode D4 of the fourth thin film transistor T4, a fifth source electrode S5 and a fifth drain electrode D5 of the fifth thin film transistor T5, are provided on the fifth insulating layer 150.

The first drain electrode D1 of the first thin film transistor T1 is electrically connected to the first active layer A1 through a contact hole provided in the second to fifth insulating layers 120, 130, 140, and 150.

The fourth drain electrode D4 of the fourth thin film transistor T4 is integrally formed with the first drain electrode D1 (e.g., D1 and D4 are formed from a same piece of wiring), and is electrically connected to the fourth active layer A4 through a contact hole provided in the second to fifth insulating layers 120, 130, 140, and 150. In addition, the fourth source electrode S4 of the fourth thin film transistor T4 is electrically connected to the fourth active layer A4 through a contact hole provided in the second to fifth insulating layers 120, 130, 140, and 150.

The fifth drain electrode D5 of the fifth thin film transistor T5 is electrically connected to the first gate electrode G1 through a contact hole provided in the third to fifth insulating layers 130, 140, and 150. The fifth source electrode S5 of the fifth thin film transistor T5 is electrically connected to the initialization line IL through a contact hole provided in the third to fifth insulating layers 130, 140, and 150.

The first drain electrode D1, the fourth source electrode S4, the fourth drain electrode D4, the fifth source electrode S5, and the fifth drain electrode D5 can be formed of the same material in the same layer through the same process.

A fifth active layer A5 is provided on the fifth source electrode S5 and the fifth drain electrode D5.

A portion of the lower surface of the fifth active layer A5 is in direct contact with the upper and side surfaces of the fifth source electrode S5 and the fifth drain electrode D5. Particularly, one end of the lower surface of the fifth active layer A5 contacts a portion of the upper surface and one side surface of the fifth source electrode S5, and the other end of the lower surface of the fifth active layer A5 contacts a portion of the upper surface and one side surface of the fifth drain electrode D5.

Therefore, according to another embodiment of the present disclosure, the lower end surface of the fifth drain electrode D5 contacts the upper surface of the first gate electrode G1, and the side surface and the upper surface of the fifth drain electrode D5 contacts the lower surface of the fifth active layer A5, so that the fifth thin film transistor T5 and the first thin film transistor T1 can be electrically connected to each other by the fifth drain electrode D5 extending into a contact hole provided in the third to fifth insulating layers 130, 140, 150, reducing the number of contact holes and the number of masks for pattern formation.

A sixth insulating layer 160 is formed on the fifth active layer A5, and a fifth gate electrode G5 of the fifth thin film transistor T5 is provided on the sixth insulating layer 160.

A seventh insulating layer 170 is provided on the fifth gate electrode G5, and a power line PL is provided on the seventh insulating layer 170.

The power line PL is electrically connected to the fourth source electrode S4 through a contact hole provided in the sixth to seventh insulating layers 160, 170.

As described above, according to another embodiment of present disclosure, the first thin film transistor T1 and the fourth thin film transistor T4 can be disposed at the same height from the lower part close to the substrate 100 or on the same layer, and the fifth thin film transistor T5 can be disposed far above the substrate 100, thereby it is possible to more easily arrange multiple thin film transistors within one pixel, and more easily arrange multiple thin film transistors within one pixel, thereby reducing the size of the pixel and improving the resolution of the display device.

In particular, when the fifth thin film transistor T5 includes the fifth active layer A5 having high mobility characteristics, since the fifth active layer A5 is directly connected to the fifth source electrode S5 and the fifth drain electrode D5 provided below it, so that the heat treatment process when the fifth source electrode S5 and the fifth drain electrode D5 are formed does not affect the fifth active layer A5, and thus high mobility characteristics of the fifth active layer A5 can be prevented from being degraded. For example, fifth source electrode S5 and the fifth drain electrode D5 can be formed before the formation of the fifth active layer A5, and the fifth active layer A5 can be disposed on top of the fifth source electrode S5 and the fifth drain electrode D5.

Also, the first thin film transistor T1 and the fifth thin film transistor T5 can be disposed at the same height near the substrate 100 or on a same layer, and the fourth thin film transistor T4 can be disposed far above the substrate 100.

In addition, in FIGS. 3 and 4, the second thin film transistor T2 or the third thin film transistor T3 can be disposed at the same height or on a same layer as the first thin film transistor T1 at a lower part close to the substrate 100.

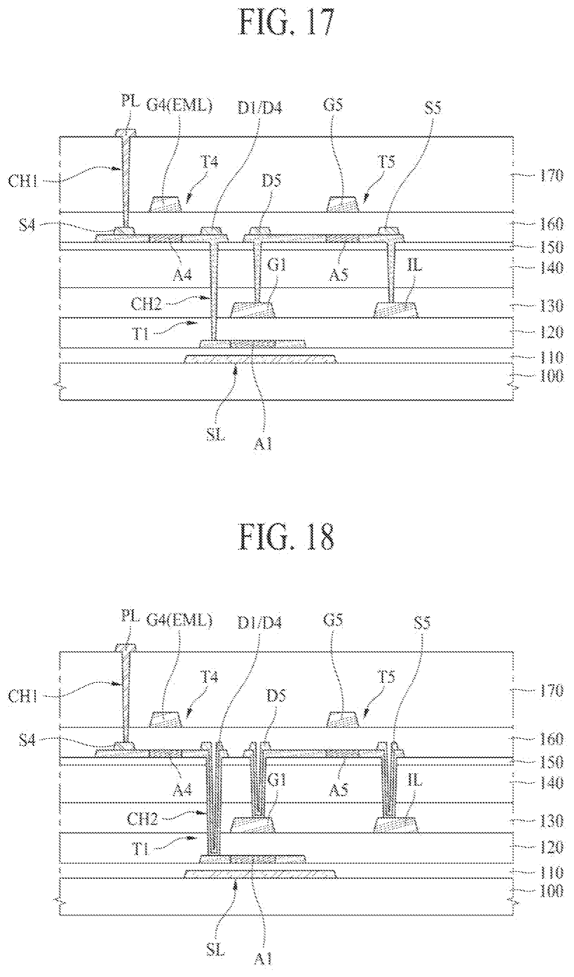

FIG. 17 is a schematic cross-sectional view of a display apparatus according to another embodiment of the present disclosure, which corresponds to cross-sections of the first thin film transistor T1, the fourth thin film transistor T4, and the fifth thin film transistor T5 in FIG. 2.

FIG. 17 is different from FIG. 5 described above in that the fourth active layer A4 directly contacts the first active layer A1 and the fifth active layer A5 directly contacts the first active layer A1. Hereinafter, only different configurations will be described.

As shown in FIG. 17, the fourth active layer A4 is connected to the first active layer A1 through a contact hole provided in the second to fifth insulating layers 120, 130, 140, and 150. In particular, a connection part of the fourth active layer A4 is connected to a connection part of the first active layer A1, and the connection part of the fourth active layer A4 extends into the contact hole provided in the second to fifth insulating layers 120, 130, 140, and 150. Therefore, the connection part of the fourth active layer A4 extending into the contact hole functions as a connection electrode connecting the first active layer A1 and the fourth active layer A4.

A fourth source electrode S4 is provided on an upper surface of one side of the fourth active layer A4, and a fourth drain electrode D4 is provided on an upper surface of the other side of the fourth active layer A4. The entire lower surface of the fourth source electrode S4 can be in contact with the upper surface of one side of the fourth active layer A4, and the entire lower surface of the fourth drain electrode D4 can be in contact with the upper surface of the other side of the fourth active layer A4.

In addition, the power line PL contacts the fourth source electrode S4 through a contact hole provided in the sixth to seventh insulating layers 160 and 170. In some situations, the power line PL can contact the fourth active layer A4 through a contact hole provided in the sixth to seventh insulating layers 160 and 170.

One side of the fifth active layer A5 is connected to the initialization line IL through a contact hole provided in the third to fifth insulating layers 130, 140 and 150. In particular, one connection part of the fifth active layer A5 is connected to the initialization line IL, and the one connection part of the fifth active layer A5 extends into the contact hole provided in the third to fifth insulating layers 130, 140, and 150. Accordingly, the one connection part on one side of the fifth active layer A5 extending into the contact hole functions as a connection electrode connecting the initialization line IL and the fifth active layer A5.

The other side of the fifth active layer A5 is connected to the first gate electrode G1 through a contact hole provided in the third to fifth insulating layers 130, 140, 150. In particular, the other connection part of the fifth active layer A5 is connected to the first gate electrode G1, and the other connection part of the fifth active layer A5 extends into the contact hole provided in the third to fifth insulating layers 130, 140, and 150. Accordingly, the other connection part of the fifth active layer A5 extending into the contact hole functions as a connection electrode connecting the first gate electrode G1 and the fifth active layer A5.

A fifth source electrode S5 is provided on an upper surface of one side of the fifth active layer A5, and a fifth drain electrode D5 is provided on an upper surface of the other side of the fifth active layer A5. The entire lower surface of the fifth source electrode S5 can be in contact with the upper surface of one side of the fifth active layer A5, and the entire lower surface of the fifth drain electrode D5 can be in contact with the upper surface of the other side of the fifth active layer A5.

According to another embodiment of the present disclosure, when the fourth active layer A4 is in contact with the first active layer A1, the fourth thin film transistor T4 and the first thin film transistor T1 can be electrically connected to each other by the fourth active layer A4 extending into the contact holes provided in the second to fifth insulating layers 120, 130, 140, and 150, thereby reducing the number of contact holes and the number of masks for pattern formation.

In addition, according to another embodiment of the present disclosure, when the fourth active layer A4 contacts the first gate electrode G1, the fifth thin film transistor T5 and the first thin film transistor T1 can be electrically connected to each other by the fourth active layer A4 extending into the contact holes provided in the second to fifth insulating layers 120, 130, 140, and 150, thereby reducing the number of contact holes and the number of masks for pattern formation.

FIG. 18 is a schematic cross-sectional view of a display apparatus according to another embodiment of the present disclosure, which corresponds to cross-sections of the first thin film transistor T1, the fourth thin film transistor T4, and the fifth thin film transistor T5 in FIG. 2.

FIG. 18 is different from FIG. 17 in that the fourth active layer A4 and the fourth drain electrode D4 extend into one contact hole, the fifth active layer A5 and the fifth drain electrode D5 extend into one contact hole, and the fifth active layer A5 and the fifth source electrode S5 extend into one contact hole.

FIGS. 17 to 18 are direct to the first thin film transistor T1, the fourth thin film transistor T4, and the fifth thin film transistor T5, and the structures according to FIGS. 17 to 18 can be applied to the second thin film transistor T2, and the third thin film transistor T3 as well.

For example, the structure between the fourth active layer A4 and the fourth source/drain electrode S4/D4 according to FIGS. 17 to 18 can be applied to the structure between the second active layer A2 and the second source/drain electrode S2/D2 and between the third active layer A3 and the third source/drain electrode S3/D3.

In addition, the structure between the fourth active layer A4, the fourth source electrode S4, and the power line PL according to FIGS. 17 to 18 can be applied to the structure between the third active layer A3, the third source electrode S3, and the first bridge electrode BE1 in FIGS. 3 and 4 or between the second active layer A2, the second drain electrode D2 and the second bridge electrode BE2 in FIG. 4.

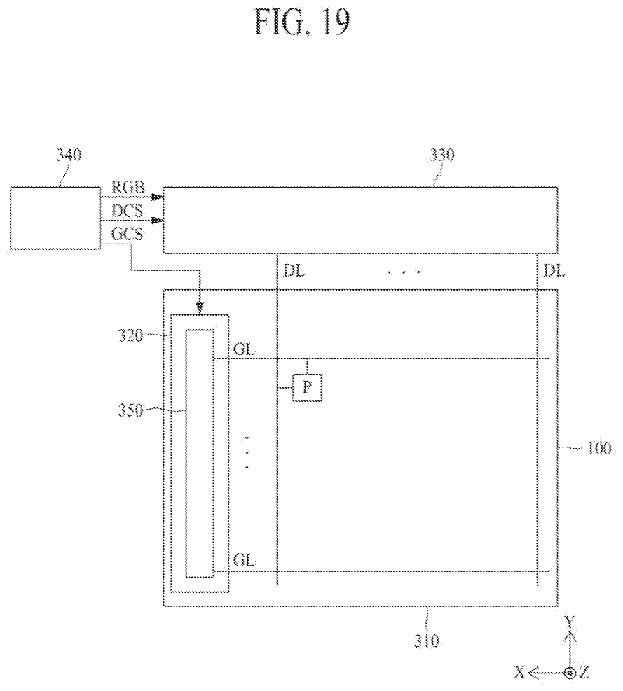

FIG. 19 is a schematic diagram of a display apparatus according to an embodiment of the present disclosure.

As shown in FIG. 19, the display apparatus according to an embodiment of the present disclosure can include a display panel 310, a gate driver 320, a data driver 330, and a controller 340.

The display panel 310 includes gate lines GLs and data lines DLs, and pixels P are disposed in respective crossing areas of the gate lines GLs and data lines DLs. An image is displayed by driving the pixel P. The gate lines GLs, the data lines DLs, and the pixels P can be disposed on the substrate 100.

The controller 340 controls the gate driver 320 and the data driver 330. The controller 340 outputs a gate control signal GCS for controlling the gate driver 320 and a data control signal DCS for controlling the data driver 330 by using a signal supplied from an external system. Also, the controller 340 samples input video data input from the external system and rearranges the sampled input video data, and supplies the rearranged digital video data RGB to the data driver 330.

The gate control signal GCS includes a gate start pulse GSP, a gate shift clock GSC, a gate output enable signal GOE, a start signal Vst, and a gate clock GCLK. Further, control signals for controlling a shift register can be included in the gate control signal GCS.

The data control signal DCS includes a source start pulse SSP, a source shift clock signal SSC, a source output enable signal SOE, and a polarity control signal POL.

The data driver 330 supplies a data voltage to the data lines DL of the display panel 310. Specifically, the data driver 330 converts the video data RGB inputted from the controller 340 into an analog data voltage and supplies the data voltage to the data lines DL.

The gate driver 320 can be mounted on the display panel 310. As described above, a structure in which the gate driver 320 is directly mounted on the display panel 310 is referred to as a gate in panel (GIP) structure. Specifically, in the gate-in-panel (GIP) structure, the gate driver 320 can be disposed on the substrate 100.

The gate driver 320 can include a shift register 350.

The shift register 350 sequentially supplies gate pulses to the gate lines GL during one frame by the use of start signal and gate clock transmitted from the controller 340. Herein, the one frame refers to a period in which one image is outputted through the display panel 310. The gate pulse has a turn-on voltage capable of turning on a switching device (thin film transistor) disposed in the pixel P.

Also, during the remaining period of one frame, in which the gate pulse is not supplied, the shift register 350 supplies a gate-off signal capable of turning off the switching device to the gate line GL. Hereinafter, the gate pulse and the gate-off signal are totally referred to as a scan signal GS.

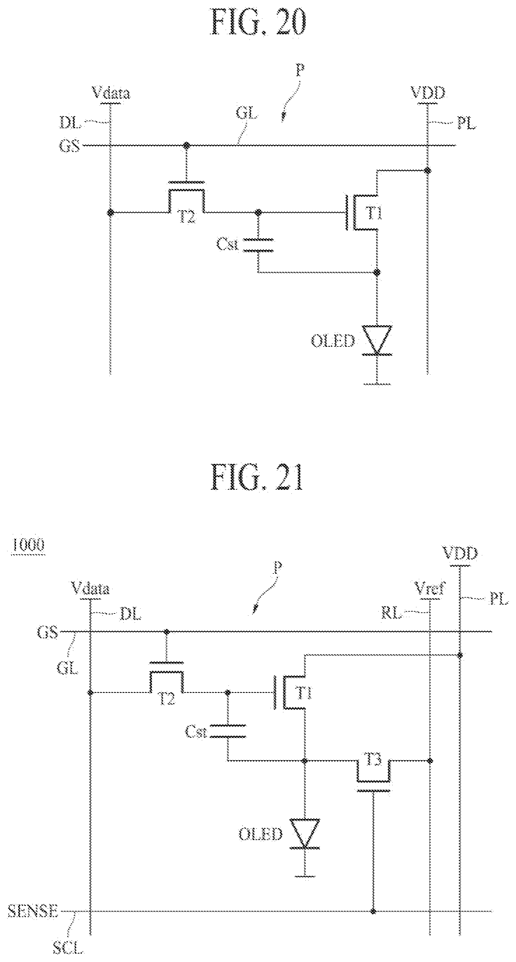

FIG. 20 is a circuit diagram of one pixel provided in a display apparatus according to an embodiment of the present disclosure.

As shown in FIG. 20, the display apparatus according to an embodiment of present disclosure includes first and second thin film transistors T1 and T2 and capacitors Cst.

The first thin film transistor T1 is a driving thin film transistor, and the second thin film transistor T2 is a switching thin film transistor.

The first thin film transistor T1 is switched according to the data voltage Vdata supplied from the second thin film transistor T2, generates a data current from the driving voltage VDD supplied from the power line PL, and supplies it to the organic light emitting diode OLED.

The second thin film transistor T2 is switched according to the gate signal GS supplied to the gate line GL and supplies the data voltage Vdata supplied from the data line DL to the first thin film transistor T1.

The electrical connection between the first thin film transistor T1 and the second thin film transistor T2 is the same as the electrical connection between the first thin film transistor T1 and the second thin film transistor T2 in various embodiments described above.

The capacitor Cst serves to maintain the data voltage supplied to the first thin film transistor T1 for one frame, and is provided between the gate electrode and the source electrode of the first thin film transistor T1.

The organic light emitting diode OLED emits predetermined light according to a data current supplied from the first thin film transistor T1.

FIG. 21 is a circuit diagram of one pixel provided in a display apparatus according to another embodiment of the present disclosure.

As shown in FIG. 21, the display apparatus according to another embodiment of present disclosure includes first to third thin film transistors T1, T2, T3 and a capacitor Cst.

The first thin film transistor T1 is a driving thin film transistor, and the second to third thin film transistors T2 to T3 are switching thin film transistors.

The first thin film transistor T1 is switched according to the data voltage Vdata supplied from the second thin film transistor T2, generates a data current from the driving voltage VDD supplied from the power line PL, and supplies it to the organic light emitting diode OLED.

The second thin film transistor T2 is switched according to the gate signal GS supplied to the gate line GL and supplies the data voltage Vdata supplied from the data line DL to the first thin film transistor T1.

The third thin film transistor T3 supplies the current of the first thin film transistor T1 to the reference line RL in response to the sensing control signal SENSE supplied from the scan line SCL. A reference voltage Vref is supplied to the reference line RL.

The electrical connection between the first thin film transistor T1, the second thin film transistor T2 and the third thin film transistor T3 is the same as the electrical connection between the first thin film transistor T1, the second thin film transistor T2 and the third thin film transistor T3 in various embodiments described above.

The capacitor Cst serves to maintain the data voltage supplied to the first thin film transistor T1 for one frame, and is provided between the gate electrode and the source electrode of the first thin film transistor T1.

The organic light emitting diode OLED emits predetermined light according to a data current supplied from the first thin film transistor T1.

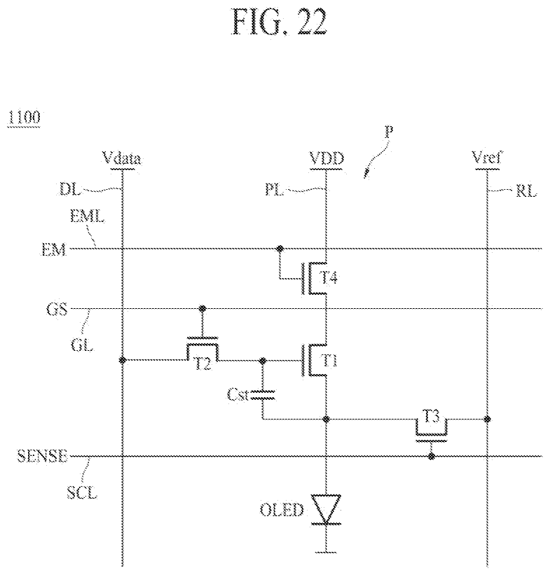

FIG. 22 is a circuit diagram of one pixel provided in a display apparatus according to another embodiment of the present disclosure.

As shown in FIG. 22, the display apparatus according to another embodiment of the present disclosure includes first to fourth thin film transistors T1, T2, T3, and T4 and a capacitor Cst.

The first thin film transistor T1 is a driving thin film transistor, and the second to fourth thin film transistors T2 to T4 are switching thin film transistors.

The first thin film transistor T1 is switched according to the data voltage Vdata supplied from the second thin film transistor T2, generates a data current from the driving voltage VDD supplied from the power line PL, and supplies it to the organic light emitting diode OLED.

The second thin film transistor T2 is switched according to the gate signal GS supplied to the gate line GL and supplies the data voltage Vdata supplied from the data line DL to the first thin film transistor T1.

The third thin film transistor T3 supplies the current of the first thin film transistor T1 to the reference line RL in response to the sensing control signal SENSE supplied from the scan line SCL. A reference voltage Vref is supplied to the reference line RL.

The fourth thin film transistor T4 is switched according to the light emission control signal EM supplied to the light emission control line EML and supplies the driving voltage VDD supplied from the power line PL to the first thin film transistor T1.

The electrical connection between the first thin film transistor T1, the second thin film transistor T2, the third thin film transistor T3 and the fourth thin film transistor T4 is the same as the electrical connection between the first thin film transistor T1, the second thin film transistor T2, the third thin film transistor T3 and the fourth thin film transistor T4 in various embodiments described above.

The capacitor Cst serves to maintain the data voltage supplied to the first thin film transistor T1 for one frame, and is provided between the gate electrode and the source electrode of the first thin film transistor T1.

The organic light emitting diode OLED emits predetermined light according to a data current supplied from the first thin film transistor T1.

Accordingly, the present disclosure can have the following advantages.

According to an embodiment of the present disclosure, since the first thin film transistor is placed close to the substrate, and the second thin film transistor is placed far above the substrate, it can be easier to place multiple thin film transistors in one pixel, thereby reducing the size of the pixel and improving the resolution of the display apparatus by being able to fit more pixels closer together.

According to an embodiment of the present disclosure, since the second active layer of the second thin film transistor is directly connected to the second source electrode or the second drain electrode provided below it, the heat treatment process used when the second source electrode and the second drain electrode are formed does not affect the second active layer, since the second active layer is formed after and on top of the second source electrode and/or the second drain electrode, and thus high mobility characteristics of the second active layer can be prevented from being degraded.

According to an embodiment of the present disclosure, since the lower end surface of the second drain electrode serving as the connection electrode contacts the upper surface of the first gate electrode of the first thin film transistor, and the side surface and the upper surface of the second drain electrode contacts the lower surface of the second active layer of the second thin film transistor, the second thin film transistor and the first thin film transistor can be electrically connected to each other by one second drain electrode, thereby reducing the number of contact holes and the number of masks for pattern formation.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

What is claimed is:

1. A thin film transistor substrate comprising:
a first thin film transistor disposed on a substrate, the first thin film transistor including a first active layer and a first gate electrode;
a second thin film transistor disposed on the substrate, the second thin film transistor including a second active layer and a second gate electrode, each of the second active layer and the second gate electrode being located farther away from the substrate than the first active layer and the first gate electrode;
a first insulating layer disposed between the first gate electrode and the second active layer; and
a first connection electrode connecting the first gate electrode with the second active layer,
wherein the first connection electrode extends through a first contact hole in the first insulating layer and contacts both of the first gate electrode and the second active layer.

2. The thin film transistor substrate according to claim 1, wherein one side of a lower surface of the second active layer is in contact with both of one side surface of the first connection electrode and a portion of an upper surface of the first connection electrode.

3. The thin film transistor substrate according to claim 1, wherein one end of the second active layer is in contact with one side of the first connection electrode.

4. The thin film transistor substrate according to claim 1, wherein the second active layer is in contact with one side of the first connection electrode, an upper surface of the first connection electrode and another side of the first connection electrode opposite to the one side.

5. The thin film transistor substrate according to claim 1, wherein the second thin film transistor further includes a second source electrode in contact with the second active layer,
wherein one side of the second active layer is in contact with the first connection electrode, and another side of the second active layer is in contact with the second source electrode, and
wherein an overlapping structure between the one side of the second active layer and the first connection electrode differs from an overlapping structure between the another side of the second active layer and the second source electrode.

6. The thin film transistor substrate according to claim 1, further comprising:
a second insulating layer disposed between the first active layer and the first gate electrode,
wherein the second insulating layer has a same pattern or a same width as the first gate electrode.

7. The thin film transistor substrate according to claim 1, wherein the second active layer includes a channel part and a connection part connected to one side of the channel part having better electrical conductivity than the channel part, and wherein the first connection electrode is in contact with the connection part.

8. The thin film transistor substrate according to claim 1, wherein the first connection electrode is a second drain electrode of the second thin film transistor.

9. The thin film transistor substrate according to claim 1, wherein the first connection electrode is formed of a portion of the second active layer of the second thin film transistor.

10. The thin film transistor substrate according to claim 9, wherein the second active layer includes a channel part and a connection part connected to one side of the channel part having better electrical conductivity than the channel part, and wherein the first connection electrode is formed of the connection part.

11. The thin film transistor substrate according to claim 9, further comprising:
a second drain electrode in contact with an upper surface of the first connection electrode.

12. The thin film transistor substrate according to claim 1, further comprising:
a third thin film transistor disposed on the substrate, the third thin film transistor including a third active layer and a third gate electrode, each of the third active layer and the third gate electrode being located farther away from the substrate than the first active layer and the first gate electrode;
a second insulating layer disposed between the first active layer and the first gate electrode; and
a second connection electrode connecting the first active layer with the second active layer,
wherein the second connection electrode extends through a second contact hole in the first insulating layer and the second insulating layer, and the second connection electrode contacts both of the first active layer and the second active layer.

13. The thin film transistor substrate according to claim 12, further comprising:
a third insulating layer disposed on the third active layer; and
a first bridge electrode disposed on the third insulating layer,
wherein the first bridge electrode is electrically connected to the second connection electrode through a third contact hole in the third insulating layer.

14. The thin film transistor substrate according to claim 13, wherein the third contact hole overlaps with the first bridge electrode and the second connection electrode, and
wherein the third contact hole does not overlap the third active layer.

15. The thin film transistor substrate according to claim 13, wherein the third contact hole overlaps with the first bridge electrode, the second connection electrode and the third active layer.

16. The thin film transistor substrate according to claim 12, wherein the third active layer is disposed on a same layer as the second active layer, and wherein the third gate electrode is disposed on a same layer as the second gate electrode.

17. The thin film transistor substrate according to claim 1, further comprising:
a third thin film transistor disposed on the substrate, the third thin film transistor including a third active layer and a third gate electrode,
wherein the third active layer is disposed on a same layer as the first active layer, and
wherein the third gate electrode is disposed on a same layer as the first gate electrode.

18. The thin film transistor substrate according to claim 1, further comprising:
a light shielding layer overlapping with the first active layer and electrically connected to the first active layer,
wherein the light shielding layer is disposed between the substrate and the first active layer.

19. The thin film transistor substrate according to claim 18, further comprising:
a first capacitor electrode electrically connected to the first gate electrode, the first capacitor electrode being disposed on a same layer as the first gate electrode; and
a second capacitor electrode electrically connected to the light shielding layer, the second capacitor electrode being disposed on a same layer as the light shielding layer.

20. The thin film transistor substrate according to claim 18, further comprising:
a first capacitor electrode disposed on a same layer as the second gate electrode, and electrically connected to the first gate electrode through a second bridge electrode; and
a second capacitor electrode disposed on a same layer as the first connection electrode, and electrically connected to the light shielding layer.

21. A display apparatus comprising:
a light emitting element disposed on a substrate;
a first thin film transistor disposed on the substrate and electrically connected to the light emitting element, the first thin film transistor including a first active layer and a first gate electrode;
a second thin film transistor disposed on the substrate, the second thin film transistor including a second active layer and a second gate electrode, each of the second active layer and the second gate electrode being located farther away from the substrate than the first active layer and the first gate electrode;
a first insulating layer disposed between the first gate electrode and the second active layer; and
a first connection electrode connecting the first gate electrode with the second active layer,
wherein the first connection electrode is extends through a first contact hole in the first insulating layer and contacts both of the first gate electrode and the second active layer.

22. A display apparatus comprising:
a light emitting element disposed on a substrate;
a first thin film transistor disposed on the substrate and including a first active layer, the first thin film transistor being electrically connected to the light emitting element;
a second thin film transistor disposed on the substrate and including a second active layer; and
a first connection electrode directly connected between the first active layer and the second active layer,
wherein the second active layer is located farther away from the substrate than the first active layer, and
wherein a portion of the second active layer directly contacts both of an upper surface of the first connection electrode and a side surface of the first connection electrode.
